(19) United States
(12) Patent Application Publication
(10) Pub. No.: US 2026/0214948 A1
(43) Pub. Date: Jul. 23, 2026

(54) DISPLAY DEVICE AND ELECTRONIC DEVICE INCLUDING THE SAME

(71) Applicant: Samsung Display Co., Ltd., Yongin-si (KR)

(72) Inventors: SEHYUN LEE, Yongin-si (KR); JI-SUN KIM, Yongin-si (KR); SUNHWA LEE, Yongin-si (KR); KWIHYUN KIM, Yongin-si (KR); KYUNGHOON CHUNG, Yongin-si (KR)

(21) Appl. No.: 19/412,685

(22) Filed: Dec. 8, 2025

(30) Foreign Application Priority Data
Jan. 21, 2025 (KR) 10-2025-0008788

(51) Int. Cl. H10D 30/67; H10D 86/40; H10D 86/60

(52) U.S. Cl. CPC H10D 30/6757; H10D 86/441; H10D 86/60

(57) ABSTRACT

A display device includes first and second active patterns including first and second driving channel areas having first and second channel lengths, respectively, the second channel length being greater than the first, a first gate pattern above the first active pattern, and including a first portion spaced from the first active pattern, a second portion overlapping the first driving channel area, and a connecting portion bent from the first portion toward the second portion and connecting the first portion and the second portion, a second gate pattern above the second active pattern and overlapping the second driving channel area, a first light-emitting element above the first active pattern, connected to the first active pattern, and configured to emit a first light, and a second light-emitting element above the second active pattern, connected to the second active pattern, and configured to emit a second light.

### CROSS-REFERENCE TO RELATED APPLICATION

The present application claims priority to, and the benefit of, Korean Patent Application No. 10-2025-0008788, filed on Jan. 21, 2025, in the Korean Intellectual Property Office, the entire disclosure of which is incorporated herein by reference.

### BACKGROUND

### 1. Field

Embodiments relate to a display device providing visual information, and an electronic device including the same.

### 2. Description of the Related Art

An electronic device, such as a smart phone, a digital camera, a notebook computer, a navigation system, a monitor, a smart television, and a smartwatch that provide images to users includes a display device for displaying images. The display device generate images and provide the generated images to users through a display screen. In general, the display devices include a pixel for generating images, and a driver for driving the pixel.

The pixel may include a light-emitting element that emits light, and pixel circuits connected to the light-emitting element. A light-emitting efficiency of the light-emitting elements varies depending on a driving current delivered from the pixel circuit. For example, by improving the light-emitting efficiency by controlling intensity of the driving current, power consumption efficiency of the display device may be improved.

### SUMMARY

Embodiments provide a display device with improved power consumption efficiency.

Embodiments provide an electronic device including the display device.

A display device according to one or more embodiments includes a first active pattern including a first driving channel area having a first channel length, a second active pattern spaced apart from the first active pattern in a plan view, and including a second driving channel area having a second channel length that is greater than the first channel length, a first gate pattern above the first active pattern, and including a first portion spaced apart from the first active pattern in the plan view, a second portion overlapping the first driving channel area of the first active pattern in a plan view, and a connecting portion bent from the first portion toward the second portion in the plan view and connecting the first portion and the second portion, a second gate pattern above the second active pattern and overlapping the second driving channel area in the plan view, a first light-emitting element above the first active pattern, electrically connected to the first active pattern, and configured to emit a first light, and a second light-emitting element above the second active pattern, electrically connected to the second active pattern, and configured to emit a second light that is different from the first light.

The second active pattern may be spaced apart from the first active pattern in a first direction, wherein the second portion is spaced apart from the first portion in a second direction crossing the first direction.

The first channel length may be defined as a length of the first driving channel area in the second direction, wherein the second channel length is defined as a length of the second driving channel area in the first direction.

A first driving transistor may include the first active pattern and the first gate pattern, and may be configured to transmit a driving current to the first light-emitting element, wherein a second driving transistor includes the second active pattern and the second gate pattern, and is configured to transmit the driving current to the second light-emitting element.

A first channel width of the first driving transistor may be defined as a width of the first driving channel area in the first direction, wherein a second channel width of the second driving transistor is defined as a width of the second driving channel area in the second direction.

A width-to-length ratio of the first channel width to the first channel length may be greater than a width-to-length ratio of the second channel width to the second channel length.

The display device may further include a first upper pattern portion at a layer between the first gate pattern and the first light-emitting element, and overlapping the first gate pattern, and a second upper pattern portion at a layer between the second gate pattern and the second light-emitting element, and overlapping the second gate pattern.

A first hole exposing an upper surface of the first portion may be defined in the first upper pattern portion.

The first upper pattern portion may overlap an entirety of the first gate pattern.

An area of a portion where the first gate pattern overlaps the first upper pattern portion may be greater than an area of a portion where the second gate pattern overlaps the second upper pattern portion.

The first gate pattern and the first upper pattern portion may define a first storage capacitor connected to a gate terminal of the first driving transistor, wherein the second gate pattern and the second upper pattern portion define a second storage capacitor connected to a gate terminal of the second driving transistor.

The display device may further include a first light-emitting control transistor connected to a first terminal of the first driving transistor, a first operation control transistor connected to a second terminal of the first driving transistor opposite to the first terminal of the first driving transistor, a second light-emitting control transistor connected to a first terminal of the second driving transistor, and a second operation control transistor connected to a second terminal of the second driving transistor opposite to the first terminal of the second driving transistor.

A channel width of the first light-emitting control transistor may be greater than a channel width of the second light-emitting control transistor.

A channel width of the first operation control transistor may be greater than a channel width of the second operation control transistor.

A display device according to one or more embodiments includes a first light-emitting element configured to emit a first light, a first driving transistor configured to transmit a first driving current to the first light-emitting element, and having a first channel length and a first channel width, a second light-emitting element configured to emit a second light that is different from the first light, and a second driving transistor configured to transmit a second driving current to the second light-emitting element, having a second channel length and a second channel width, and having a width-to-length ratio of the second channel width to the second channel length that is less than a width-to-length ratio of the first channel width to the first channel length of the first driving transistor.

The first channel length of the first driving transistor may be less than the second channel length of the second driving transistor.

An intensity of the first driving current may be greater than an intensity of the second driving current.

The display device may further include a first light-emitting control transistor including a first terminal connected to a first terminal of the first driving transistor, and a second terminal connected to the first light-emitting element, a first operation control transistor including a first terminal configured to receive a driving voltage, and a second terminal connected to a second terminal of the first driving transistor opposite to the first terminal of the first driving transistor, a second light-emitting control transistor including a first terminal connected to a first terminal of the second driving transistor, and a second terminal connected to the second light-emitting element, and a second operation control transistor including a first terminal configured to receive the driving voltage, and a second terminal connected to a second terminal of the second driving transistor opposite to the first terminal of the second driving transistor, wherein a channel width of the first light-emitting control transistor is greater than a channel width of the second light-emitting control transistor.

A channel width of the first operation control transistor may be greater than a channel width of the second operation control transistor.

An electronic device according to one or more embodiments includes a processor configured to output image data and an input control signal, and a display device configured to be driven based on the image data and the input control signal, and including a first active pattern including a first driving channel area having a first channel length, a second active pattern spaced apart from the first active pattern in a plan view, and including a second driving channel area having a second channel length that is greater than the first channel length, a first gate pattern above the first active pattern, and including a first portion spaced apart from the first active pattern in the plan view, a second portion overlapping the first driving channel area of the first active pattern in a plan view, and a connecting portion bent from the first portion toward the second portion in the plan view, and connecting the first portion and the second portion, a second gate pattern above the second active pattern, and overlapping the second driving channel area in the plan view, a first light-emitting element above the first active pattern, electrically connected to the first active pattern, and configured to emit a first light, and a second light-emitting element above the second active pattern, electrically connected to the second active pattern, and configured to emit a second light that is different from the first light.

In a display device according to embodiments of the present disclosure, a first gate pattern included in a first driving transistor arranged in a first sub-pixel area may include a first portion that does not overlap a first active pattern in a plan view, and a second portion that overlaps the first active pattern in the plan view.

Accordingly, a length in a second direction of a first driving channel of the first active pattern included in the first driving transistor arranged in the first sub-pixel area may be less than a length in a first direction of a second driving channel of a second active pattern included in a second driving transistor arranged in a second sub-pixel area. As a result, a width-to-length ratio of a channel width and a channel length may be greater for the first driving transistor included in the first sub-pixel area than the second driving transistor. Therefore, because a current flowing through the first driving transistor that drives a first light-emitting element for emitting red light may be greater than a current flowing through the second driving transistor, a power consumption efficiency of the display device may be improved.

### BRIEF DESCRIPTION OF DRAWINGS

Illustrative, non-limiting embodiments will be more clearly understood from the following detailed description in conjunction with the accompanying drawings.

FIG. 1 is a block diagram illustrating a display device according to one or more embodiments of the present disclosure.

FIG. 2 is a circuit diagram illustrating a sub-pixel included in the display device of FIG. 1.

FIG. 3 is a cross-sectional view illustrating a portion of the display panel of FIG. 1.

FIGS. 4, 5, 6, 7, 8, 9, 10, 11, 12, 13, 14, 15, 16, 17, and 18 are layout views for explaining a pixel included in the display device of FIG. 1.

FIG. 19 is a cross-sectional view illustrating cross-sections taken along the lines I-I′ and II-II′ of FIG. 18.

FIG. 20 is a diagram for comparing a magnitude of driving current delivered to each of the first, second, and third sub-pixels.

FIG. 21 is a block diagram illustrating a display device according to one or more other embodiments of the present disclosure.

FIGS. 22, 23, and 24 are layout views for explaining a pixel included in the display device of FIG. 22.

FIG. 25 is a block diagram illustrating an electronic device according to one or more embodiments of the present disclosure.

FIG. 26 is a diagram illustrating the electronic device of FIG. 25 implemented as a smartphone.

FIG. 27 is a diagram illustrating the electronic device of FIG. 25 implemented as a smartwatch.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and/or the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

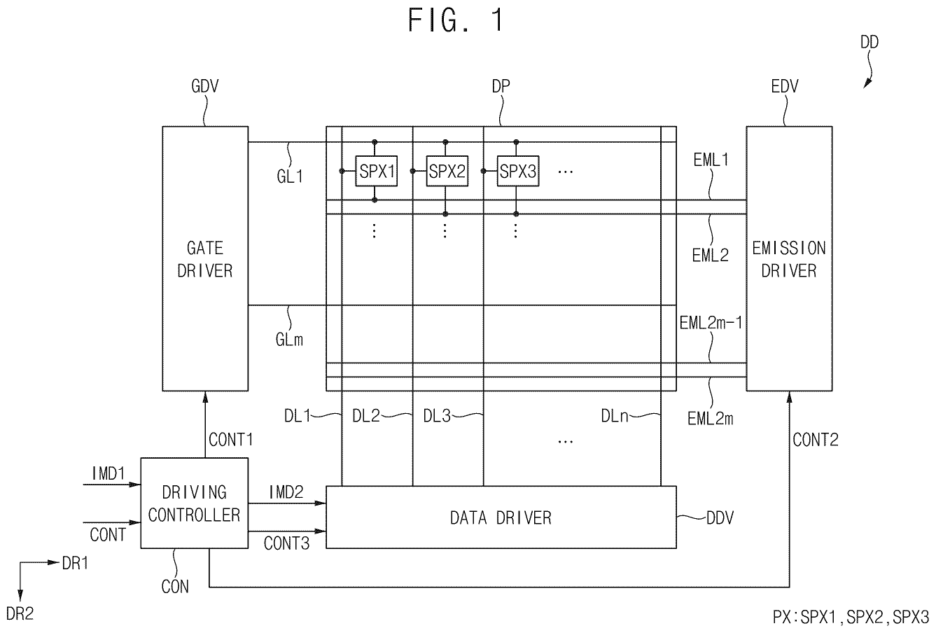

FIG. 1 is a block diagram illustrating a display device according to one or more embodiments of the present disclosure.

Referring to FIG. 1, a display device DD according to one or more embodiments of the present disclosure may include a display panel DP, a driving controller CON, a gate driver GDV, an emission driver EDV, and a data driver DDV.

The display panel DP may include a display area defined as an area for displaying images, and a peripheral area adjacent to the display area. The display area may include a plurality of pixels PX, a plurality of gate lines GL1, . . . , GLm, a plurality of light-emitting control lines EML1, EML2, . . . , EML2m-1, EML2m, and a plurality of data lines DL1, DL2, DL3, . . . , DLn. The peripheral area may be arranged with the gate driver GDV, the emission driver EDV, and the data driver DDV.

In the disclosure, a plane may be defined by a first direction DR1 and a second direction DR2 crossing the first direction DR1. For example, the second direction DR2 may be perpendicular to the first direction DR1. In addition, a third direction DR3 may be perpendicular to the plane.

The plurality of pixels PX may be arranged in a matrix form including a plurality of pixel rows and a plurality of pixel columns. The plurality of pixels PX may be arranged along the first direction DR1 and the second direction DR2. One of the pixels PX may include sub-pixels that emit light of different colors. For example, one pixel may include a first sub-pixel SPX1 that emits a first color light, a second sub-pixel SPX2 that emits a second color light, and a third sub-pixel SPX3 that emits a third color light.

In one or more embodiments, the first color light may be red light, the second color light may be green light, and the third color light may be blue light. However, the colors of the light emitted by the first sub-pixel SPX1, the second sub-pixel SPX2, and the third sub-pixel SPX3 according to embodiments of the present disclosure may not be limited thereto. For example, the first sub-pixel SPX1, the second sub-pixel SPX2, and the third sub-pixel SPX3 may be configured to emit magenta light, cyan light, and yellow light, respectively.

Each of the plurality of gate lines GL1, . . . , GLm may extend along the first direction DR1. Each of the plurality of gate lines GL1, . . . , GLm may be spaced apart from one another in the second direction DR2. Each of the plurality of light-emitting control lines EML1, EML2, . . . , EML2m-1, EML2m may extend along the first direction DR1. Each of the plurality of light-emitting control lines EML1, EML2, . . . , EML2m-1, EML2m may be spaced apart from one another in the second direction DR2. Each of the plurality of data lines DL1, DL2, DL3, . . . , DLn may extend along the second direction DR2. Each of the plurality of data lines DL1, DL2, DL3, . . . , DLn may be spaced apart from one another in the first direction DR1.

In one or more embodiments, a sub-pixel included in one pixel among the plurality of pixels PX may be electrically connected to one gate line among the plurality of gate lines GL1, . . . , GLm, one light-emitting control line among the plurality of light-emitting control lines EML1, EML2, . . . , EML2m-1, EML2m, and one data line among the plurality of data lines DL1, DL2, DL3, . . . , DLn. For example, the first sub-pixel SPX1 may be electrically connected to the first gate line GL1, the first light-emitting control line EML1, and the first data line DL1. The second sub-pixel SPX2 may be electrically connected to the first gate line GL1, the second light-emitting control line EML2, and the second data line DL2. The third sub-pixel SPX3 may be electrically connected to the first gate line GL1, the second light-emitting control line EML2, and the third data line DL3.

In one or more embodiments, sub-pixels arranged in a same row along the row direction (e.g., the first direction DR1) may be electrically connected to a same gate line. In one or more embodiments, sub-pixels arranged in a same column along the column direction (e.g., the second direction DR2) may be electrically connected to a same data line.

In one or more embodiments, sub-pixels that emit the first color light and that are arranged in a same row along the row direction may be electrically connected to a same light-emitting control line. In one or more embodiments, sub-pixels that emit the second color light and sub-pixels that emit the third color light, both being arranged in a same row along the row direction, may be electrically connected to a same light-emitting control line. However, connection relationship between the sub-pixels and the light-emitting control lines according to embodiments of the present disclosure may not be limited thereto, and all sub-pixels arranged in a same row may be electrically connected to a same light-emitting control line.

The driving controller CON may receive input image data IMD1 and input control signals CONT from a host processor (e.g., a graphic processing unit, GPU). In one or more embodiments, the input image data IMD1 may include red image data, green image data, and blue image data. In one or more embodiments, the input image data IMD1 may further include white image data. In one or more other embodiments, the input image data IMD1 may include magenta image data, yellow image data, and cyan image data. The input control signals CONT may include a master clock signal and a data enable signal. The input control signals CONT may further include a vertical sync signal and a horizontal sync signal.

The driving controller CON may generate a gate control signal CONT1, a light-emitting control signal CONT2, a data control signal CONT3, and second image data IMD2 based on the input image data IMD1 and the input control signals CONT.

The driving controller CON may generate the gate control signal CONT1 for controlling the operation of the gate driver GDV based on the input control signals CONT, and output the gate control signal CONT1 to the gate driver GDV. The gate control signal CONT1 may include a vertical start signal and a gate clock signal.

The driving controller CON may generate the light-emitting control signal CONT2 for controlling the operation of the emission driver EDV based on the input control signals CONT, and may output the light-emitting control signal CONT2 to the emission driver EDV. The light-emitting control signal CONT2 may include a light-emitting clock signal, a light-emitting start signal, and/or the like.

The driving controller CON may generate the data control signal CONT3 for controlling the operation of the data driver DDV based on the input control signals CONT, and may output the data control signal CONT3 to the data driver DDV. The data control signal CONT3 may include a horizontal start signal and a load signal.

The driving controller CON may generate the second image data IMD2 based on the input image data IMD1 and the input control signals CONT. The driving controller CON may output the second image data IMD2 to the data driver DDV. The second image data IMD2 may include a plurality of grayscale values corresponding to the pixels PX.

The gate driver GDV may generate gate signals for driving the plurality of gate lines GL1, . . . , GLm in response to the gate control signal CONT1 received from the driving controller CON. The gate driver GDV may sequentially output the gate signals to each of the plurality of gate lines GL1 to GLm. Each of the plurality of gate lines GL1, . . . , GLm may transmit the gate signals.

The emission driver EDV may generate light-emitting signals for driving the plurality of light-emitting control lines EML1, EML2, . . . , EML2m-1, EML2m in response to the light-emitting control signal CONT2 received from the driving controller CON. The emission driver EDV may sequentially output the light-emitting signals to each of the plurality of light-emitting control lines EML1, EML2, . . . , EML2m-1, EML2m. Each of the plurality of light-emitting control lines EML1, EML2, . . . , EML2m-1, EML2m may transmit the light-emitting signals.

The data driver DDV may receive the data control signal CONT3 and the second image data IMD2 from the driving controller CON. The data driver DDV may generate data voltages by converting the second image data IMD2 into analog voltages. The data driver DDV may output the data voltages to each of the plurality of data lines DL1, DL2, DL3, . . . , DLn. In one or more embodiments, the data driver DDV may be mounted on the display panel DP or may be integrated in the vicinity of the display panel DP. In one or more other embodiments, the data driver DDV may be implemented as one or more integrated circuits IC. Each of the plurality of data lines DL1, DL2, DL3, . . . , DLn may transmit the data signals. Each pixel PX may display an image based on the gate signals, the light-emitting signals, and the gate signals.

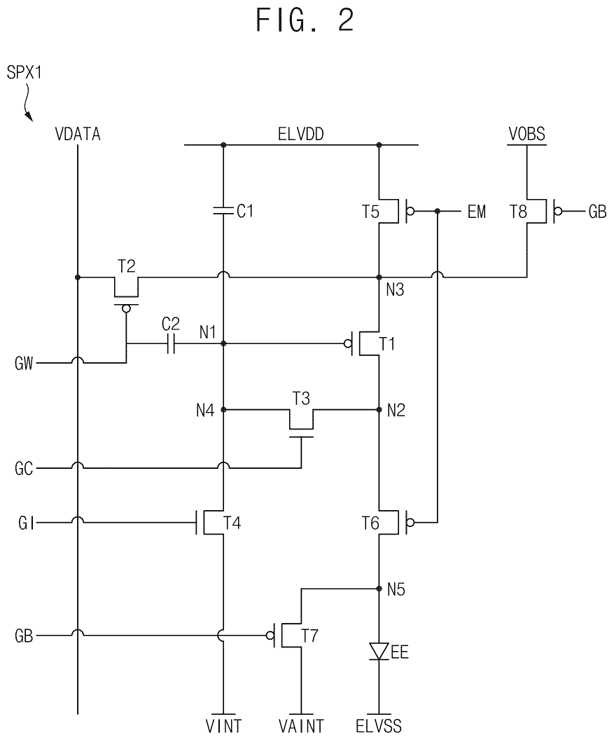

FIG. 2 is a circuit diagram illustrating a sub-pixel included in the display device of FIG. 1.

Referring to FIG. 2, the first sub-pixel SPX1 may include a pixel circuit and a light-emitting element EE. The pixel circuit may include a first transistor T1, a second transistor T2, a third transistor T3, a fourth transistor T4, a fifth transistor T5, a sixth transistor T6, a seventh transistor T7, an eighth transistor T8, a first capacitor C1, and a second capacitor C2. The pixel circuit may provide a driving current to the light-emitting element EE, and the light-emitting element EE may generate first light based on the driving current.

The first transistor T1 may include a gate terminal connected to a first node N1, a first terminal connected to a second node N2, and a second terminal connected to a third node N3. The first terminal of the first transistor T1 may be connected to the light-emitting element EE, and the second terminal of the first transistor T1 may be connected to a data voltage line. Accordingly, the first transistor T1 may receive a data voltage VDATA from the data voltage line and may generate a driving current corresponding to the data voltage VDATA. The driving current may be supplied to the light-emitting element EE. In one or more embodiments, the first transistor T1 may be a driving transistor.

The second transistor T2 may include a first terminal connected to the data voltage line, a second terminal connected to the third node N3, and a gate terminal for receiving a write signal GW. Accordingly, the second transistor T2 may be turned on or off by the write signal GW. During a period in which the second transistor T2 is turned on, the second transistor T2 may supply the data voltage VDATA to the first transistor T1. In other words, the second transistor T2 may transfer the data voltage VDATA to the third node N3 in response to the write signal GW. The second transistor T2 may be a write transistor.

The third transistor T3 may include a first terminal connected to the second node N2, a second terminal connected to a fourth node N4, and a gate terminal for receiving a compensation signal GC. Accordingly, the third transistor T3 may be turned on or off by the compensation signal GC. During a period in which the third transistor T3 is turned on, it may compensate for the threshold voltage of the first transistor T1 by diode-connecting the first transistor T1. In one or more embodiments, the third transistor T3 may be a compensation transistor.

The fourth transistor T4 may include a first terminal connected to the fourth node N4, a second terminal connected to a first initialization voltage line, and a gate terminal for receiving a gate initialization signal GI. Accordingly, the fourth transistor T4 may be turned on or off by the gate initialization signal GI. During a period in which the fourth transistor T4 is turned on, it may supply a first initialization voltage VINT, provided by the first initialization voltage line, to the gate terminal of the first transistor T1. In one or more embodiments, the fourth transistor T4 may be a first initialization transistor.

The fifth transistor T5 may include a first terminal connected to a first power voltage line, a second terminal connected to the third node N3, and a gate terminal connected to a light-emitting control line. For example, the fifth transistor T5 may be connected to the second terminal of the first transistor T1.

The light-emitting control line may supply a light-emitting signal EM to the gate terminal of the fifth transistor T5. Accordingly, the fifth transistor T5 may be turned on or off by the light-emitting signal EM. During a period in which the fifth transistor T5 is turned on, it may supply a first power voltage ELVDD, provided by the first power voltage line, to the first transistor T1. In one or more embodiments, the fifth transistor T5 may be an operation control transistor. In this disclosure, the first power voltage ELVDD may be referred to as a driving voltage.

In one or more embodiments, each of the first power voltage ELVDD provided by the first power voltage line and a second power voltage ELVSS provided by a second power voltage line connected to the light-emitting element EE may be a constant voltage. In this case, the first power voltage ELVDD and the second power voltage ELVSS may have a different voltage level.

The sixth transistor T6 may include a first terminal connected to the second node N2, a second terminal connected to a fifth node N5, and a gate terminal connected to the light-emitting control line. For example, the sixth transistor T6 may be connected to the first terminal of the first transistor T1.

The sixth transistor T6 may be turned on or off by the light-emitting signal EM. During a period in which the sixth transistor T6 is turned on, it may provide the driving current to the light-emitting element EE. In one or more embodiments, the sixth transistor T6 may be a light-emitting control transistor.

The seventh transistor T7 may include a first terminal connected to a second initialization voltage line, a second terminal connected to the fifth node N5, and a gate terminal for receiving a bypass signal GB. Accordingly, the seventh transistor T7 may be turned on or off by the bypass signal GB. During a period in which the seventh transistor T7 is turned on, it may provide a second initialization voltage VAINT, supplied by the second initialization voltage line, to the light-emitting element EE. In one or more embodiments, the seventh transistor T7 may be a second initialization transistor.

The eighth transistor T8 may include a first terminal connected to the third node N3, a second terminal for receiving a bias voltage VOBS, and a gate terminal for receiving the bypass signal GB. Accordingly, the eighth transistor T8 may be turned on or off by the bypass signal GB. During a period in which the eighth transistor T8 is turned on, the bias voltage VOBS may be delivered to the third node N3. That is, as the eighth transistor T8 is turned on and the bias voltage VOBS is applied to the third node N3, the voltage at the third node N3 may change to the bias voltage VOBS, thereby altering the characteristic curve of the first transistor T1. As a result, luminance variation due to hysteresis of the first transistor T1 may be improved.

For example, the bias voltage VOBS may be set to a voltage (e.g., a predetermined voltage, such as a DC voltage) in the voltage range of the data voltage VDATA or to a gate-on voltage, such as the write signal GW. The bias voltage VOBS may be varied based on the driving time of a driving frame (e.g., a frame rate of the panel driving frame) of the display panel (e.g., the display panel DP in FIG. 1). Accordingly, because the bias voltage VOBS changes in accordance with the operating frequency of the display panel, luminance variation due to hysteresis of the first transistor T1 may be efficiently improved.

The first capacitor C1 may include a first electrode connected to the first node N1 and a second electrode connected to the first power voltage line. The first capacitor C1 may maintain the voltage level of the first transistor T1 during a deactivation period of the write signal GW.

The second capacitor C2 may include a third electrode connected to the gate terminal of the second transistor T2, and a gate line for supplying the write signal GW, and a fourth electrode connected to the first node N1. The second capacitor C2 may raise the voltage of the first node N1 when the write signal GW supplied from the gate line is turned off. When the voltage of the first node N1 increases, black grayscale may be clearly represented. In one or more embodiments, the second capacitor C2 may be a boosting capacitor.

The light-emitting element EE may include a first terminal (e.g., an anode terminal) and a second terminal (e.g., a cathode terminal). The first terminal of the light-emitting element EE may be connected to the sixth transistor T6 and the seventh transistor T7, and the second terminal may receive the second power voltage ELVSS. The light-emitting element EE may generate light of luminance corresponding to the driving current.

In FIG. 2, a circuit structure of the first sub-pixel SPX1 is illustrated, although the second sub-pixel SPX2 and the third sub-pixel SPX3 of FIG. 1 may have substantially a same circuit structure as the first sub-pixel SPX1.

In FIG. 2, the first transistor T1, second transistor T2, fifth transistor T5, sixth transistor T6, seventh transistor T7, and eighth transistor T8 are depicted as PMOS transistors, and the third transistor T3 and fourth transistor T4 are depicted as NMOS transistors. However, the types of the first, second, third, fourth, fifth, sixth, seventh, and eighth transistors T1, T2, T3, T4, T5, T6, T7, and T8 according to embodiments of the present disclosure may not be limited thereto.

In addition, the number of transistors included in one sub-pixel may not be limited to eight. One sub-pixel may include seven or fewer, or nine or more, transistors.

In addition, the number of capacitors included in one sub-pixel may not be limited to two. One sub-pixel may include one capacitor or three or more capacitors.

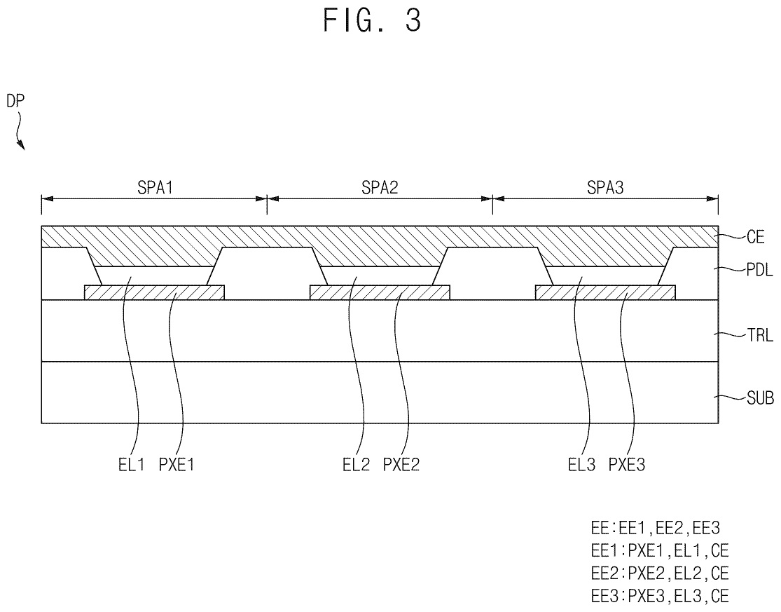

FIG. 3 is a cross-sectional view illustrating a portion of the display panel of FIG. 1.

Referring to FIGS. 1, 2, and 3, the display panel DP may include a first sub-pixel area SPA1, a second sub-pixel area SPA2, and a third sub-pixel area SPA3. The first sub-pixel area SPA1 may correspond to the first sub-pixel SPX1, the second sub-pixel area SPA2 may correspond to the second sub-pixel SPX2, and the third sub-pixel area SPA3 may correspond to the third sub-pixel SPX3. The light-emitting element EE may include a first light-emitting element EE1 arranged in the first sub-pixel area SPA1, a second light-emitting element EE2 arranged in the second sub-pixel area SPA2, and a third light-emitting element EE3 arranged in the third sub-pixel area SPA3.

The display panel DP may include a substrate SUB, a transistor layer TRL, a first pixel electrode PXE1, a second pixel electrode PXE2, a third pixel electrode PXE3, a pixel-defining layer PDL, a first light-emitting layer EL1, a second light-emitting layer EL2, a third light-emitting layer EL3, and a common electrode CE. The first pixel electrode PXE1, the first light-emitting layer EL1, and the common electrode CE may define the first light-emitting element EE1. The second pixel electrode PXE2, the second light-emitting layer EL2, and the common electrode CE may define the second light-emitting element EE2. The third pixel electrode PXE3, the third light-emitting layer EL3, and the common electrode CE may define the third light-emitting element EE3.

The substrate SUB may include a transparent material or an opaque material. The substrate SUB may include a transparent resin substrate. For example, the transparent resin substrate may include a polyimide substrate. In a case of the transparent resin substrate, the polyimide substrate may include a first organic layer, a first barrier layer, and a second organic layer. In one or more other embodiments, the substrate SUB may include a quartz substrate, a synthetic quartz substrate, a calcium fluoride substrate, a non-alkali glass substrate, and/or the like. These may be used alone or in combination.

The transistor layer TRL may include at least one transistor for driving the light-emitting element EE. For example, in the first sub-pixel area SPA1, the transistor layer TRL may include the first, second, third, fourth, fifth, sixth, seventh, and eighth transistors T1, T2, T3, T4, T5, T6, T7, and T8 included in the first sub-pixel SPX1. In the second sub-pixel area SPA2, the transistor layer TRL may include the first, second, third, fourth, fifth, sixth, seventh, and eighth transistors T1, T2, T3, T4, T5, T6, T7, and T8 included in the second sub-pixel SPX2. In the third sub-pixel area SPA3, the transistor layer TRL may include the first, second, third, fourth, fifth, sixth, seventh, and eighth transistors T1, T2, T3, T4, T5, T6, T7, and T8 included in the third sub-pixel SPX3.

The transistor layer TRL may include at least one inorganic insulating layer, at least one organic insulating layer, and at least one conductive layer. For example, the transistor layer TRL may have a structure in which the inorganic insulating layer, the conductive layer, and the organic insulating layer are alternately stacked in a corresponding order.

The first, second, and third pixel electrodes PXE1, PXE2, and PXE3 may be arranged on the transistor layer TRL. For example, each of the first, second, and third pixel electrodes PXE1, PXE2, and PXE3 may be electrically connected to a transistor included in the transistor layer TRL through a hole defined in the transistor layer TRL. The first, second, and third pixel electrodes PXE1, PXE2, and PXE3 may include the same material. For example, the pixel electrodes may include a metal, an alloy, a metal nitride, a conductive metal oxide, a transparent conductive material, and/or the like. These may be used alone or in combination.

The pixel-defining layer PDL may be arranged on the transistor layer TRL together with the first, second, and third pixel electrodes PXE1, PXE2, and PXE3. The pixel-defining layer PDL may partially cover the pixel electrodes. In addition, the pixel-defining layer PDL may define holes exposing at least portions of the first, second, and third pixel electrodes PXE1, PXE2, and PXE3. For example, the holes of the pixel-defining layer PDL may expose central portions of the first, second, and third pixel electrodes PXE1, PXE2, and PXE3, and the pixel-defining layer PDL may cover edge portions of the pixel electrodes. The pixel-defining layer PDL may include an organic insulating material, such as polyimide.

The first, second, and third light-emitting layers EL1, EL2, and EL3 may be arranged on the first, second, and third pixel electrodes PXE1, PXE2, and PXE3. For example, the light-emitting layers may be arranged on the first, second, and third pixel electrodes PXE1, PXE2, and PXE3 that are exposed through the holes of the pixel-defining layer PDL. The first, second, and third light-emitting layers EL1, EL2, and EL3 may include a same material. For example, they may include organic light-emitting materials, quantum dots, and/or the like.

The first, second, and third pixel electrodes PXE1, PXE2, and PXE3 may overlap the first, second, and third sub-pixel areas SPA1, SPA2, and SPA3, respectively. The first, second, and third light-emitting layers EL1, EL2, and EL3 may overlap the first, second, and third sub-pixel areas SPA1, SPA2, and SPA3, respectively.

The common electrode CE may be arranged on the light-emitting layers EL and the pixel-defining layer PDL. The common electrode CE may include aluminum, platinum Pt, silver, magnesium Mg, gold Au, chromium Cr, tungsten, titanium Ti, and/or the like. These may be used alone or in combination.

An encapsulation layer or a window layer for protecting the light-emitting element EE may further be arranged on the common electrode CE. In addition, an optical functional layer, such as a color filter layer, a polarizing layer, and a light-shielding layer for controlling refraction, visibility, or shielding of light emitted from each of the first, second, and third light-emitting layers EL1, EL2, and EL3 may further be arranged on the common electrode CE.

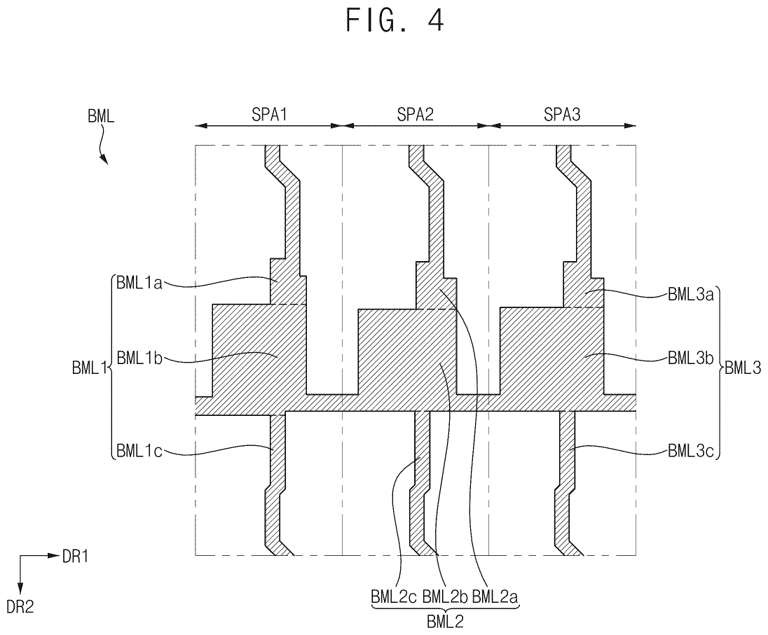

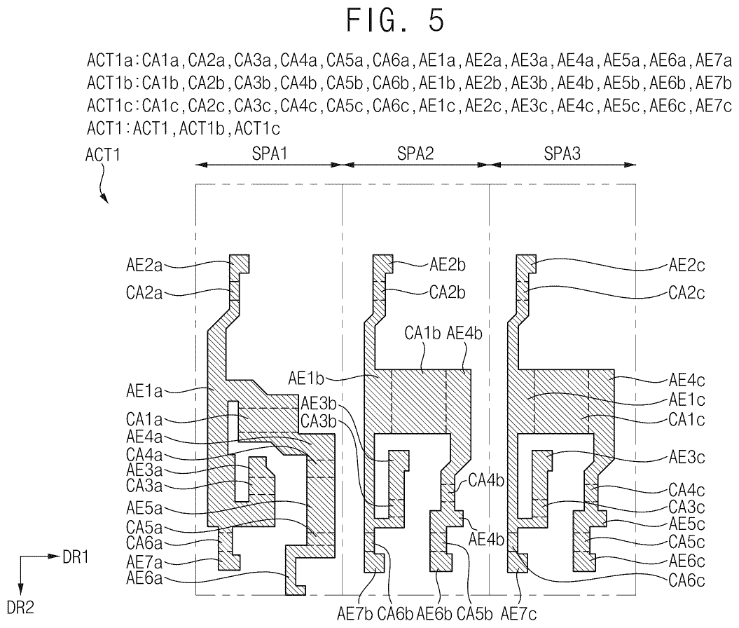

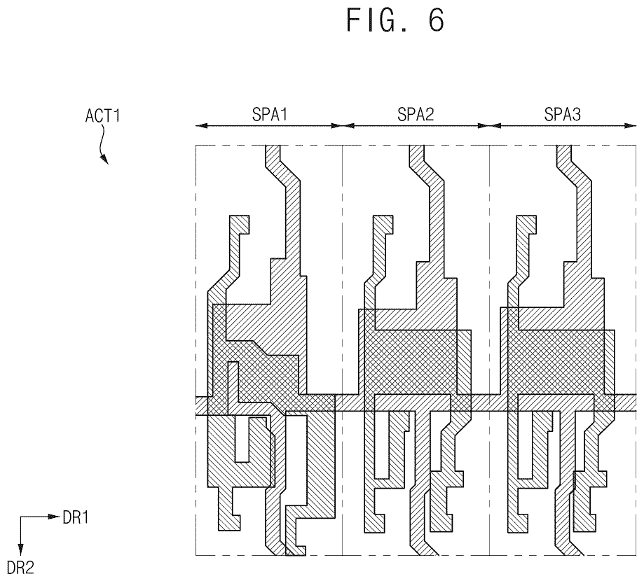

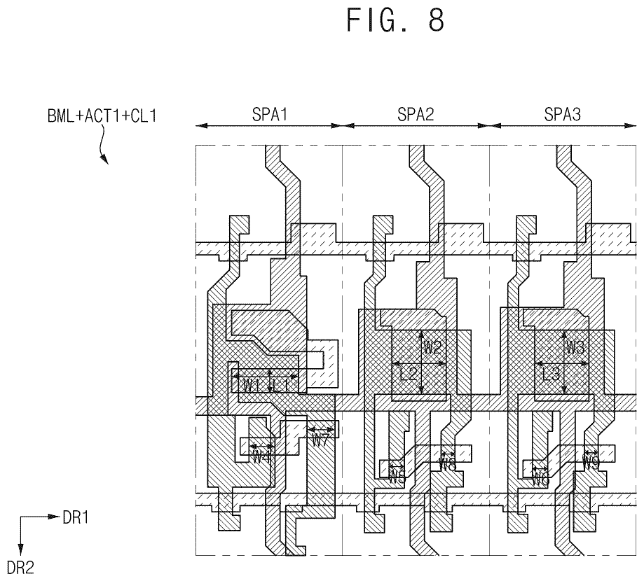

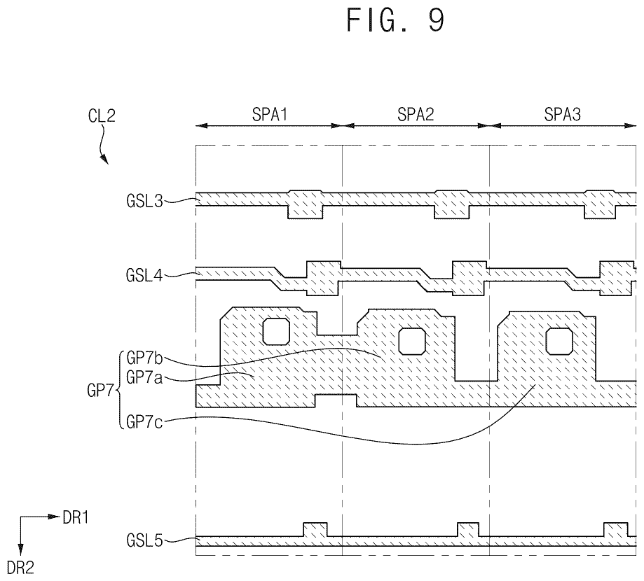

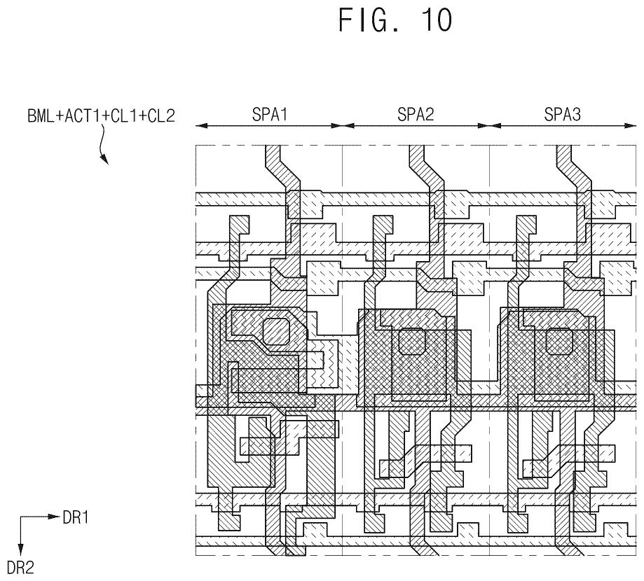

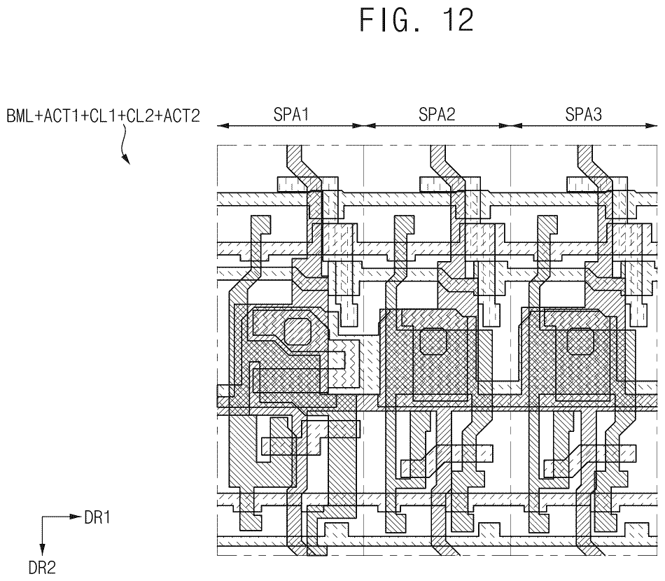

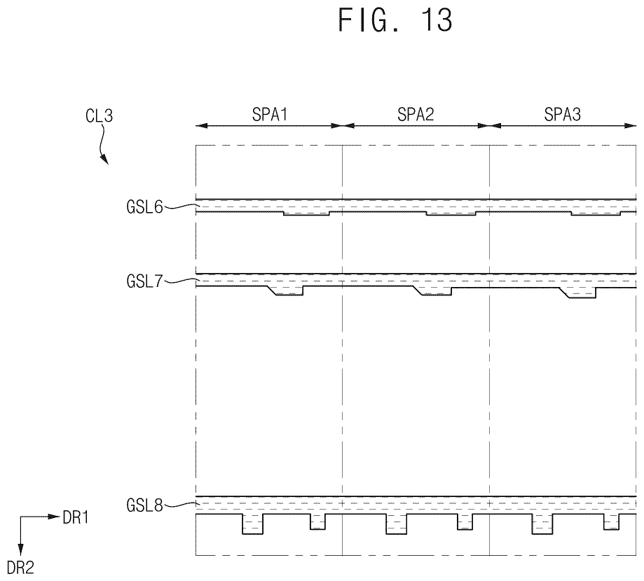

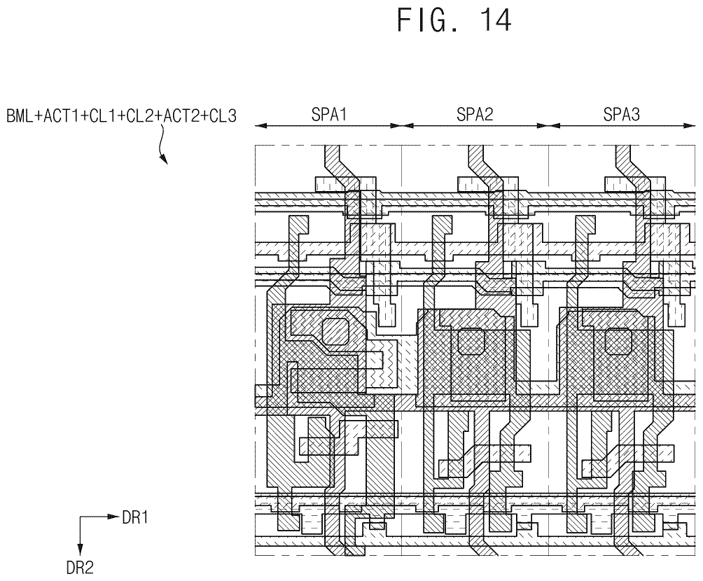

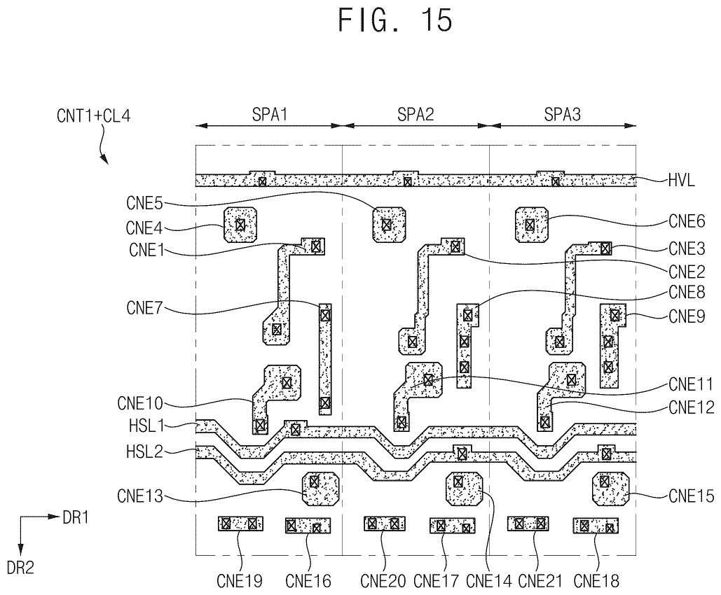

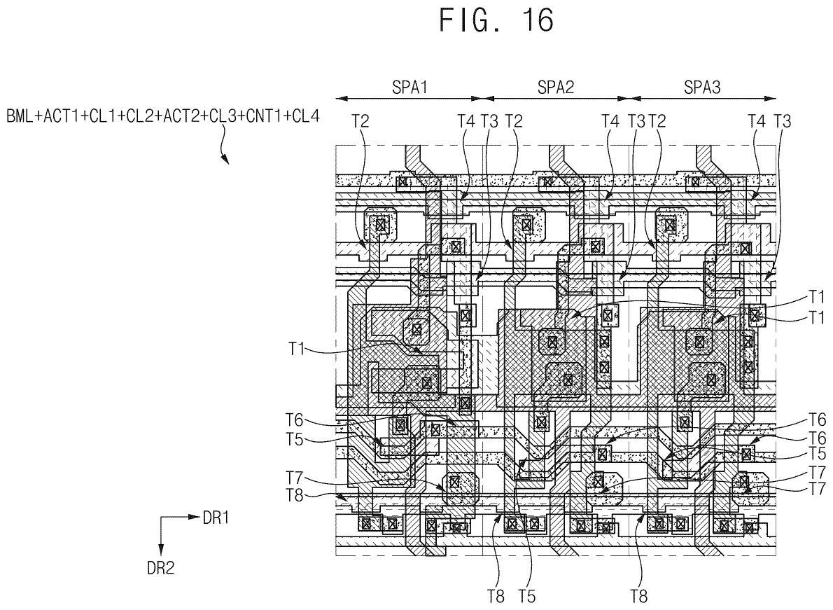

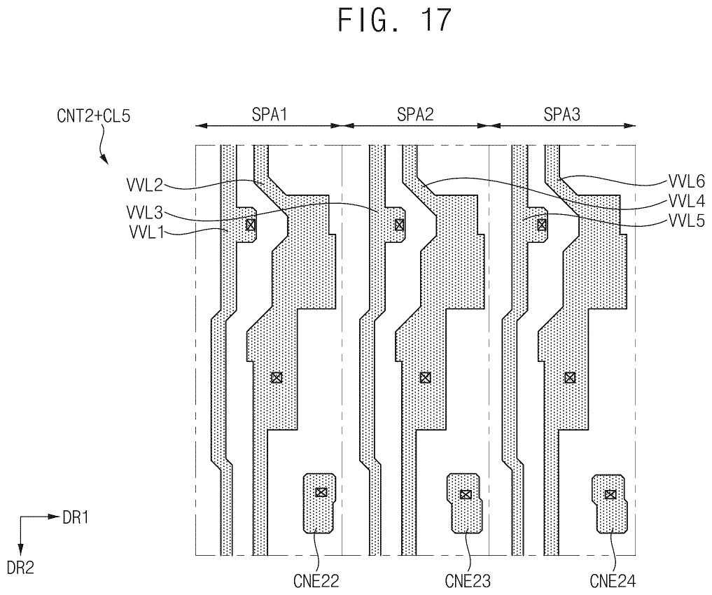

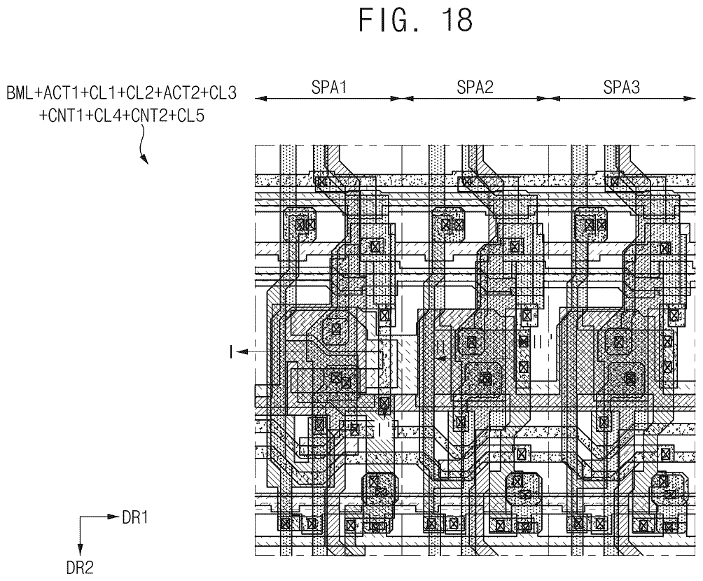

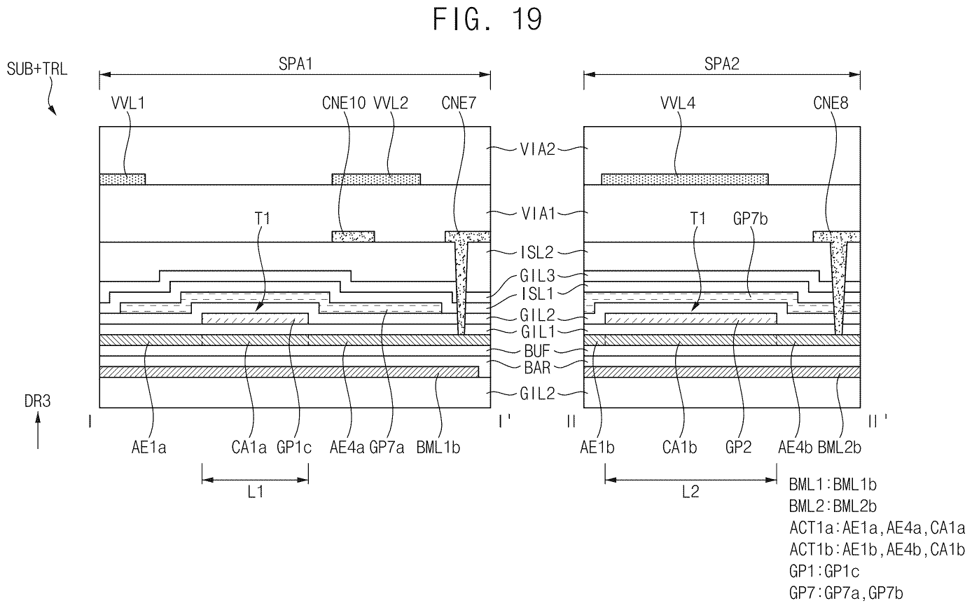

FIGS. 4, 5, 6, 7, 8, 9, 10, 12, 13, 14, 15, 16, 17, and 18 are layout views for explaining a pixel included in the display device of FIG. 1. FIG. 19 is a cross-sectional view illustrating cross-sections taken along the lines I-I′ and II-II′ of FIG. 18.

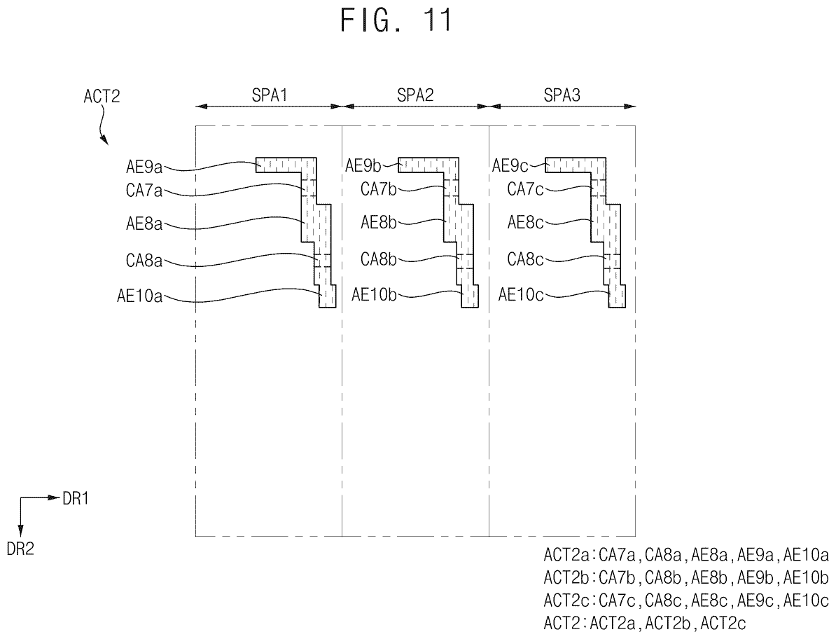

Referring to FIGS. 1, 2, 3, 4, 5, 6, 7, 8, 9, 10, 11, 12, 13, 14, 15, 16, 17, 18, and 19, components arranged between the substrate SUB and the first, second, and third pixel electrodes PXE may define the transistor layer TRL. For example, the transistor layer TRL may include a bottom metal layer BML, a barrier layer BAR, a buffer layer BUF, a first active layer ACT1, a first gate-insulating layer GIL1, a first conductive layer CL1, a second gate-insulating layer GIL2, a second conductive layer CL2, a first interlayer insulating layer ILS1, a second active layer ACT2, a third gate-insulating layer GIL3, a third conductive layer CL3, a second interlayer insulating layer ISL2, a fourth conductive layer CL4, a first via insulating layer VIA1, and a fifth conductive layer CL5.

The bottom metal layer BML may be arranged on the substrate SUB (as used herein, “arranged on” may mean “above”). In one or more embodiments, the bottom metal layer BML may include a conductive material. For example, the conductive material may include molybdenum Mo, copper Cu, aluminum Al, titanium Ti, and/or the like. These may be used alone or in combination.

The bottom metal layer BML may be arranged to extend across the first, second, and third sub-pixel areas SPA1, SPA2, and SPA3. The bottom metal layer BML may include a first bottom metal layer BML1 arranged in the first sub-pixel area SPA1, a second bottom metal layer BML2 arranged in the second sub-pixel area SPA2, and a third bottom metal layer BML3 arranged in the third sub-pixel area SPA3.

The first bottom metal layer BML1 may include a first portion BML1a, a second portion BML1b, and a third portion BML1c. The first portion BML1a may extend along the second direction DR2. The second portion BML1b may be adjacent to the first portion BML1a in the second direction DR2. The third portion BML1c may be adjacent to the second portion BML1b in the second direction DR2 and may extend along the second direction DR2.

The second bottom metal layer BML2 may include a first portion BML2a, a second portion BML2b, and a third portion BML2c. The first portion BML2a may extend along the second direction DR2. The second portion BML2b may be adjacent to the first portion BML2a in the second direction DR2. The third portion BML2c may be adjacent to the second portion BML2b in the second direction DR2 and may extend along the second direction DR2.

The third bottom metal layer BML3 may include a first portion BML3a, a second portion BML3b, and a third portion BML3c. The first portion BML3a may extend along the second direction DR2. The second portion BML3b may be adjacent to the first portion BML3a in the second direction DR2. The third portion BML3c may be adjacent to the second portion BML3b in the second direction DR2 and may extend along the second direction DR2.

In one or more embodiments, the first, second, and third bottom metal layers BML1, BML2, and BML3 may be integrally formed. For example, the second portion BML1b of the first bottom metal layer BML1, the second portion BML2b of the second bottom metal layer BML2, and the second portion BML3b of the third bottom metal layer BML3 may be integrally formed with one another. In one or more embodiments, the first portion BML1a of the first bottom metal layer BML1, the first portion BML2a of the second bottom metal layer BML2, and the first portion BML3a of the third bottom metal layer BML3 may be spaced apart from one another in the first direction DR1. The third portion BML1c of the first bottom metal layer BML1, the third portion BML2c of the second bottom metal layer BML2, and the third portion BML3c of the third bottom metal layer BML3 may be spaced apart from one another in the first direction DR1.

In one or more embodiments, shapes of the first, second, and third bottom metal layers BML1, BML2, and BML3 may be substantially a same, in a plan view. However, the bottom metal layer BML according to embodiments of the present disclosure may not be limited thereto, and shapes of the first, second, and third bottom metal layers BML1, BML2, and BML3 may be different from each other, in a plan view.

A barrier layer BAR may be arranged on the bottom metal layer BML. The barrier layer BAR may block impurities, such as oxygen and moisture from diffusing to the upper side of the substrate SUB through the substrate. In addition, the barrier layer BAR may provide a flat upper surface on the substrate SUB. In one or more embodiments, the barrier layer BAR may include an inorganic insulating material. For example, the inorganic insulating material may include silicon nitride, silicon oxide, silicon oxynitride, and/or the like. These may be used alone or in combination.

A buffer layer BUF may be arranged on the barrier layer BAR. The buffer layer BUF may block impurities, such as oxygen and moisture from diffusing to the upper side of the substrate SUB. In addition, the buffer layer BUF may provide a flat upper surface on the substrate SUB. The buffer layer BUF may include an inorganic insulating material.

The first active layer ACT1 may be arranged on the buffer layer BUF. In one or more embodiments, the first active layer ACT1 may include a silicon semiconductor. However, the material included in the first active layer ACT1 according to embodiments of the present disclosure may not be limited thereto, and the first active layer ACT1 may include various materials, such as amorphous silicon, oxide semiconductors, and organic semiconductors.

The first active layer ACT1 may include a first active pattern ACT1a arranged in the first sub-pixel area SPA1, a second active pattern ACT1b arranged in the second sub-pixel area SPA2, and a third active pattern ACT1c arranged in the third sub-pixel area SPA3. In one or more embodiments, the first active pattern ACT1a, the second active pattern ACT1b, and the third active pattern ACT1c may be spaced apart from each other in the first direction DR1.

The first active pattern ACT1a may include a first area AE1a, a second area AE2a, a third area AE3a, a fourth area AE4a, a fifth area AE5a, a sixth area AE6a, a seventh area AE7a, a first channel area CA1a, a second channel area CA2a, a third channel area CA3a, a fourth channel area CA4a, a fifth channel area CA5a, and a sixth channel area CA6a. In one or more embodiments, the first, second, third, fourth, fifth, sixth, and seventh areas AE1a to AE7a may be doping areas doped with a P-type dopant. The first, second, third, fourth, fifth, and sixth channel areas CA1a to CA6a may be areas doped at a lower concentration than the doping areas, or undoped areas.

The second active pattern ACT1b may include a first area AE1b, a second area AE2b, a third area AE3b, a fourth area AE4b, a fifth area AE5b, a sixth area AE6b, a seventh area AE7b, a first channel area CA1b, a second channel area CA2b, a third channel area CA3b, a fourth channel area CA4b, a fifth channel area CA5b, and a sixth channel area CA6b. In one or more embodiments, the first, second, third, fourth, fifth, sixth, and seventh areas AE1b to AE7b may be doping areas doped with a P-type dopant. The first, second, third, fourth, fifth, and sixth channel areas CA1b to CA6b may be areas doped at a lower concentration than the doping areas, or undoped areas. Hereinafter, descriptions of the second active pattern ACT1b overlapping with the descriptions of the first active pattern ACT1a may be omitted or simplified.

The third active pattern ACT1c may include a first area AE1c, a second area AE2c, a third area AE3c, a fourth area AE4c, a fifth area AE5c, a sixth area AE6c, a seventh area AE7c, a first channel area CA1c, a second channel area CA2c, a third channel area CA3c, a fourth channel area CA4c, a fifth channel area CA5c, and a sixth channel area CA6c. The third active pattern ACT1c may be substantially the same as the second active pattern ACT1b. Hereinafter, descriptions of the third active pattern ACT1c overlapping with the second active pattern ACT1b may be omitted or simplified.

However, the type of dopant doped into the first active layer ACT1 according to embodiments of the present disclosure may not be limited thereto, and the dopant in the first active layer ACT1 may be an N-type dopant.

In the disclosure, the first channel area CA1a of the first active pattern ACT1a may be referred to as a first driving channel area, and the first channel area CA1b of the second active pattern ACT1b or the first channel area CA1c of the third active pattern ACT1c may be referred to as a second driving channel area.

In one or more embodiments, a shape of the first active pattern ACT1a may be different from each of shapes of the second active pattern ACT1b and the third active pattern ACT1c, in a plan view. In one or more embodiments, shapes of the second active pattern ACT1b and the third active pattern ACT1c may be substantially a same, in a plan view. However, the first active layer ACT1 according to embodiments of the present disclosure may not be limited thereto, and a shape of at least one of the second active pattern ACT1b or the third active pattern ACT1c may be substantially a same as a shape of the first active pattern ACT1a, in a plan view.

The first channel area CA1a of the first active pattern ACT1a may correspond to the channel of the first transistor T1 arranged in the first sub-pixel area SPA1. In the first active pattern ACT1a, the first channel area CA1a may be adjacent to each of the first area AE1a and the fourth area AE4a. For example, the first channel area CA1a may be adjacent in the second direction DR2 from one end of the first area AE1a, and may be adjacent in the opposite direction of the second direction DR2 from one end of the fourth area AE4a.

The first channel area CA1b of the second active pattern ACT1b may correspond to the channel of the first transistor T1 arranged in the second sub-pixel area SPA2. In the second active pattern ACT1b, the first channel area CA1b may be adjacent to each of the first area AE1b and the fourth area AE4b. For example, the first channel area CA1b may be adjacent in the first direction DR1 from one end of the first area AE1b, and may be adjacent in the opposite direction of the first direction DR1 from one end of the fourth area AE4b. The first channel area CA1c of the third active pattern ACT1c may correspond to the channel of the first transistor T1 arranged in the third sub-pixel area SPA3.

In the first active pattern ACT1a, the first area AE1a may be adjacent to the third channel area CA3a. In the first active pattern ACT1a, the third channel area CA3a may correspond to the channel of the fifth transistor T5 arranged in the first sub-pixel area SPA1. In the second active pattern ACT1b, the third channel area CA3a may correspond to the channel of the fifth transistor T5 arranged in the second sub-pixel area SPA2. In the third active pattern ACT1c, the third channel area CA3c may correspond to the channel of the fifth transistor T5 arranged in the third sub-pixel area SPA3.

In the disclosure, the first transistor T1 arranged in the first sub-pixel area SPA1 may be referred to as a first driving transistor, and the first transistor T1 arranged in the second sub-pixel area SPA2 or the third sub-pixel area SPA3 may be referred to as a second driving transistor. In the disclosure, the fifth transistor T5 arranged in the first sub-pixel area SPA1 may be referred to as a first operation control transistor, and the fifth transistor T5 arranged in the second sub-pixel area SPA2 or the third sub-pixel area SPA3 may be referred to as a second operation control transistor. In the disclosure, the sixth transistor T6 arranged in the first sub-pixel area SPA1 may be referred to as a first light-emitting control transistor, and the sixth transistor T6 arranged in the second sub-pixel area SPA2 or the third sub-pixel area SPA3 may be referred to as a second light-emitting control transistor.

In the first active pattern ACT1a, the fourth area AE4a may be adjacent to the fourth channel area CA4a in the second direction DR2. In the first active pattern ACT1a, the fourth channel area CA4a may correspond to the channel of the sixth transistor T6 arranged in the first sub-pixel area SPA1. In the second active pattern ACT1b, the fourth channel area CA4b may correspond to the channel of the sixth transistor T6 arranged in the second sub-pixel area SPA2. In the third active pattern ACT1c, the fourth channel area CA4c may correspond to the channel of the sixth transistor T6 arranged in the third sub-pixel area SPA3.

In the first active pattern ACT1a, the fourth channel area CA4a may be adjacent to the fifth area AE5a in the second direction DR2. In the first active pattern ACT1a, the fifth channel area CA5a may be adjacent to the fifth area AE5a in the second direction DR2. In the first active pattern ACT1a, the fifth channel area CA5a may correspond to the channel of the seventh transistor T7 arranged in the first sub-pixel area SPA1. In the second active pattern ACT1b, the fifth channel area CA5b may correspond to the channel of the seventh transistor T7 arranged in the second sub-pixel area SPA2. In the third active pattern ACT1c, the fifth channel area CA5c may correspond to the channel of the seventh transistor T7 arranged in the third sub-pixel area SPA3.

In the first active pattern ACT1a, the first area AE1a may be adjacent to the sixth channel area CA6a in the second direction DR2. In the first active pattern ACT1a, the sixth channel area CA6a may correspond to the channel of the eighth transistor T8 arranged in the first sub-pixel area SPA1. In the second active pattern ACT1b, the sixth channel area CA6b may correspond to the channel of the eighth transistor T8 arranged in the second sub-pixel area SPA2. In the third active pattern ACT1c, the sixth channel area CA6c may correspond to the channel of the eighth transistor T8 arranged in the third sub-pixel area SPA3.

In one or more embodiments, a length of a portion extending from the first channel area CA1a of the first active pattern ACT1a and bent toward the second direction DR2 may be greater than a length of a portion extending from the first channel area CA1b of the second active pattern ACT1b in the first direction DR1 and bent toward the second direction DR2.

For example, a length defined along a profile of the fourth area AE4a, the fourth channel area CA4a, the fifth area AE5a, and the sixth area AE6a of the first active pattern ACT1a may be greater than a length defined along a profile of the fourth area AE4b, the fourth channel area CA4b, the fifth area AE5b, and the sixth area AE6b of the second active pattern ACT1b. In addition, in one or more embodiments, a length of the portion extending from the first channel area CA1a of the first active pattern ACT1a and bent toward the second direction DR2 may be greater than a length of the portion extending from the first channel area CA1c of the third active pattern ACT1c in the first direction DR1 and bent toward the second direction DR2.

The first bottom metal layer BML1 may overlap the first active pattern ACT1a in a plan view. For example, the second portion BML1b of the first bottom metal layer BML1 may overlap a portion of the first area AE1a, the first channel area CA1a, and a portion of the fourth area AE4a of the first active pattern ACT1a in a plan view.

The second bottom metal layer BML2 may overlap the second active pattern ACT1b in a plan view. For example, the second portion BML2b of the second bottom metal layer BML2 may overlap a portion of the first area AE1b, the first channel area CA1b, and a portion of the fourth area AE4b of the second active pattern ACT1b in a plan view.

The third bottom metal layer BML3 may overlap the third active pattern ACT1c in a plan view. For example, the second portion BML3b of the third bottom metal layer BML3 may overlap a portion of the first area AE1c, the first channel area CA1c, and a portion of the fourth area AE4c of the third active pattern ACT1c in a plan view.

The first gate-insulating layer GIL1 may be arranged on the first active layer ACT1. The first gate-insulating layer GIL1 may cover the first active layer ACT1. The first gate-insulating layer GIL1 may have a substantially uniform thickness along the profile of the first active layer ACT1. However, the first gate-insulating layer GIL1 according to embodiments of the present disclosure may not be limited thereto, and the first gate-insulating layer GIL1 may have a substantially flat upper surface without forming steps around the first active layer ACT1. In one or more embodiments, the first gate-insulating layer GIL1 may include an inorganic insulating material.

The first conductive layer CL1 may be arranged on the first gate-insulating layer GIL1. In one or more embodiments, the first conductive layer CL1 may include a conductive material. The first conductive layer CL1 may include a first gate line GSL1, a second gate line GSL2, a first gate pattern GP1, a second gate pattern GP2, a third gate pattern GP3, a fourth gate pattern GP4, a fifth gate pattern GP5, and a sixth gate pattern GP6. The first gate line GSL1, the second gate line GSL2, the first gate pattern GP1, the second gate pattern GP2, the third gate pattern GP3, the fourth gate pattern GP4, the fifth gate pattern GP5, and the sixth gate pattern GP6 may be spaced apart from each other in a plan view.

The first gate line GSL1 may be arranged across the first, second, and third sub-pixel areas SPA1, SPA2, and SPA3. For example, the first gate line GSL1 may extend along the first direction DR1. In one or more embodiments, the first gate line GSL1 may overlap a portion of the first active layer ACT1 in a plan view. For example, the first gate line GSL1 may overlap the second channel area CA2a of the first active pattern ACT1a, the second channel area CA2b of the second active pattern ACT1b, and the second channel area CA2c of the third active pattern ACT1c in a plan view. A write signal GW may be applied to the first gate line GSL1. Accordingly, the first gate line GSL1 may define the gate terminal of the second transistor T2 arranged in each of the first, second, and third sub-pixel areas SPA1, SPA2, and SPA3.

In one or more embodiments, the second channel area CA2a of the first active pattern ACT1a may define the channel area of the second transistor T2 arranged in the first sub-pixel area SPA1. In one or more embodiments, the second channel area CA2b of the second active pattern ACT1b may define the channel area of the second transistor T2 arranged in the second sub-pixel area SPA2. In one or more embodiments, the second channel area CA2c of the third active pattern ACT1c may define the channel area of the second transistor T2 arranged in the third sub-pixel area SPA3.

The second gate line GSL2 may be arranged across the first, second, and third sub-pixel areas SPA1, SPA2, and SPA3. For example, the second gate line GSL2 may extend along the first direction DR1. In one or more embodiments, the second gate line GSL2 may overlap a portion of the first active layer ACT1 in a plan view. For example, the second gate line GSL2 may overlap the fifth channel area CA5a and the sixth channel area CA6a of the first active pattern ACT1a, the fifth channel area CA5b and the sixth channel area CA6b of the second active pattern ACT1b, and the fifth channel area CA5c and the sixth channel area CA6c of the third active pattern ACT1c in a plan view.

The bypass signal GB may be applied to the second gate line GSL2. Accordingly, the second gate line GSL2 may define the gate terminal of the seventh transistor T7 arranged in each of the first, second, and third sub-pixel areas SPA1, SPA2, and SPA3. In addition, the second gate line GSL2 may define the gate terminal of the eighth transistor T8 arranged in each of the first, second, and third sub-pixel areas SPA1, SPA2, and SPA3.

The fifth channel area CA5a of the first active pattern ACT1a may be the channel of the seventh transistor T7 arranged in the first sub-pixel area SPA1. The fifth channel area CA5b of the second active pattern ACT1b may be the channel of the seventh transistor T7 arranged in the second sub-pixel area SPA2. The fifth channel area CA5c of the third active pattern ACT1c may be the channel of the seventh transistor T7 arranged in the third sub-pixel area SPA3.

The sixth channel area CA6a of the first active pattern ACT1a may be the channel of the eighth transistor T8 arranged in the first sub-pixel area SPA1. The sixth channel area CA6b of the second active pattern ACT1b may be the channel of the eighth transistor T8 arranged in the second sub-pixel area SPA2. The sixth channel area CA6c of the third active pattern ACT1c may be the channel of the eighth transistor T8 arranged in the third sub-pixel area SPA3.

The first gate pattern GP1 may be arranged in the first sub-pixel area SPA1. The first gate pattern GP1 may include a first portion GP1a, a connecting portion GP1b, and a second portion GP1c. The first portion GP1a, the connecting portion GP1b, and the second portion GP1c may be integrally formed. In one or more embodiments, the first gate pattern GP1 may be spaced apart from the first gate line GSL1 in the second direction DR2.

In one or more embodiments, the first portion GP1a of the first gate pattern GP1 may be spaced apart from the first gate line GSL1 in the second direction DR2. In one or more embodiments, the first portion GP1a may not overlap (e.g., may be separated from in plan view) the first active pattern ACT1a. In one or more embodiments, the first portion GP1a may overlap the second portion BML1b of the first bottom metal layer BML1 in a plan view.

In one or more embodiments, the second portion GP1c of the first gate pattern GP1 may overlap a portion of the first active pattern ACT1a in a plan view. For example, the second portion GP1c may overlap the first channel area CA1a of the first active pattern ACT1a in a plan view. As the second portion GP1c overlaps the first channel area CA1a of the first active pattern ACT1a, the second portion GP1c may define the gate electrode of the first transistor T1 arranged in the first sub-pixel area SPA1. In addition, as the second portion GP1c overlaps the first channel area CA1a of the first active pattern ACT1a, the first channel area CA1a may define the channel of the first transistor T1 arranged in the first sub-pixel area SPA1. In other words, the portion of the first gate pattern GP1 of the first active pattern ACT1a overlapping with the second portion GP1c may be the first channel area CA1a of the first active pattern ACT1a.

The connecting portion GP1b of the first gate pattern GP1 may connect the first portion GP1a and the second portion GP1c to each other. For example, the connecting portion GP1b may be bent in a plan view from the first portion GP1a toward the second portion GP1c. For example, the connecting portion GP1b may protrude, or extend, in the first direction DR1 from one end of the first portion GP1a, may be bent and extended along the second direction DR2, and may be bent and extended in the opposite direction of the first direction DR1 toward one end of the second portion GP1c.

In one or more embodiments, the connecting portion GP1b of the first gate pattern GP1 may be spaced apart from the first active pattern ACT1a in a plan view. In other words, the connecting portion GP1b of the first gate pattern GP1 may not overlap, or may be separated from, the first active pattern ACT1a in a plan view.

In one or more embodiments, the connecting portion GP1b of the first gate pattern GP1 may be spaced apart from the first bottom metal layer BML1 in a plan view. In other words, the connecting portion GP1b of the first gate pattern GP1 may not overlap the first bottom metal layer BML1 in a plan view.

The second gate pattern GP2 may be arranged in the second sub-pixel area SPA2. In one or more embodiments, the second gate pattern GP2 may be spaced apart from the first gate signal line GSL1 in the second direction DR2. In one or more embodiments, the second gate pattern GP2 may be spaced apart from the first gate pattern GP1 in the first direction DR1.

In one or more embodiments, the second gate pattern GP2 may overlap a portion of the second active pattern ACT1b. For example, the second gate pattern GP2 may overlap the first channel area CA1b of the second active pattern ACT1b in a plan view. As the second gate pattern GP2 overlaps the first channel area CA1b of the second active pattern ACT1b, the gate electrode of the first transistor T1 arranged in the second sub-pixel area SPA2 may be defined. In addition, as the second gate pattern GP2 overlaps the first channel area CA1b of the second active pattern ACT1b, the first channel area CA1b may define the channel of the first transistor T1 arranged in the second sub-pixel area SPA2. In other words, the portion of the second active pattern ACT1b that overlaps the second gate pattern GP2 may be the first channel area CA1b of the second active pattern ACT1b.

The third gate pattern GP3 may be arranged in the third sub-pixel area SPA3. In one or more embodiments, the third gate pattern GP3 may be spaced apart from the first gate signal line GSL1 in the second direction DR2. In one or more embodiments, the third gate pattern GP3 may be spaced apart from the second gate pattern GP2 in the first direction DR1.

According to one or more embodiments, the third gate pattern GP3 may overlap a portion of the third active pattern ACT1c. For example, the third gate pattern GP3 may overlap the first channel area CA1c of the third active pattern ACT1c in a plan view. As the third gate pattern GP3 overlaps the first channel area CA1c of the third active pattern ACT1c, the gate electrode of the first transistor T1 arranged in the third sub-pixel area SPA3 may be defined. In addition, as the third gate pattern GP3 overlaps the first channel area CA1c of the third active pattern ACT1c, the first channel area CA1c may define the channel of the first transistor T1 arranged in the third sub-pixel area SPA3. In other words, the portion of the third active pattern ACT1c that overlaps the third gate pattern GP3 may be the first channel area CA1c of the third active pattern ACT1c.

The fourth gate pattern GP4 may be arranged in the first sub-pixel area SPA1. In one or more embodiments, the fourth gate pattern GP4 may be spaced apart from the first gate pattern GP1 in the second direction DR2. In one or more embodiments, the fourth gate pattern GP4 may overlap the first active pattern ACT1a in a plan view. For example, the fourth gate pattern GP4 may overlap the third channel area CA3a and the fourth channel area CA4a of the first active pattern ACT1a in a plan view.

As the fourth gate pattern GP4 overlaps the third channel area CA3a of the first active pattern ACT1a, the gate electrode of the fifth transistor T5 arranged in the first sub-pixel area SPA1 may be defined. In addition, as the fourth gate pattern GP4 overlaps the third channel area CA3a of the first active pattern ACT1a, the third channel area CA3a may define the channel of the fifth transistor T5 arranged in the first sub-pixel area SPA1.

As the fourth gate pattern GP4 overlaps the fourth channel area CA4a of the first active pattern ACT1a, the gate electrode of the sixth transistor T6 arranged in the first sub-pixel area SPA1 may be defined. In addition, as the fourth gate pattern GP4 overlaps the fourth channel area CA4a of the first active pattern ACT1a, the fourth channel area CA4a may define the channel of the sixth transistor T6 arranged in the first sub-pixel area SPA1.

The fifth gate pattern GP5 may be arranged in the second sub-pixel area SPA2. In one or more embodiments, the fifth gate pattern GP5 may be spaced apart from the second gate pattern GP2 in the second direction DR2. In one or more embodiments, the fifth gate pattern GP5 may be spaced apart from the second gate pattern GP2 in the second direction DR2. In one or more embodiments, the fifth gate pattern GP5 may be spaced apart from the fourth gate pattern GP4 in the first direction DR1.

In one or more embodiments, the fifth gate pattern GP5 may overlap the second active pattern ACT1b in a plan view. For example, the fifth gate pattern GP5 may overlap the third channel area CA3b and the fourth channel area CA4b of the second active pattern ACT1b in a plan view.

As the fifth gate pattern GP5 overlaps the third channel area CA3b of the second active pattern ACT1b, the gate electrode of the fifth transistor T5 arranged in the second sub-pixel area SPA2 may be defined. In addition, as the fifth gate pattern GP5 overlaps the third channel area CA3b of the second active pattern ACT1b, the third channel area CA3b may define the channel of the fifth transistor T5 arranged in the second sub-pixel area SPA2.

As the fifth gate pattern GP5 overlaps the fourth channel area CA4b of the second active pattern ACT1b, the gate electrode of the sixth transistor T6 arranged in the second sub-pixel area SPA2 may be defined. In addition, as the fifth gate pattern GP5 overlaps the fourth channel area CA4b of the second active pattern ACT1b, the fourth channel area CA4b may define the channel of the sixth transistor T6 arranged in the second sub-pixel area SPA2.

The sixth gate pattern GP6 may be arranged in the third sub-pixel area SPA3. In one or more embodiments, the sixth gate pattern GP6 may be spaced apart from the third gate pattern GP3 in the second direction DR2. In one or more embodiments, the sixth gate pattern GP6 may be spaced apart from the fifth gate pattern GP5 in the first direction DR1.

In one or more embodiments, the sixth gate pattern GP6 may overlap the third active pattern ACT1c in a plan view. For example, the sixth gate pattern GP6 may overlap the third channel area CA3c and the fourth channel area CA4c of the third active pattern ACT1c in a plan view.

As the sixth gate pattern GP6 overlaps the third channel area CA3c of the third active pattern ACT1c, the gate electrode of the fifth transistor T5 arranged in the third sub-pixel area SPA3 may be defined. In addition, as the sixth gate pattern GP6 overlaps the third channel area CA3c of the third active pattern ACT1c, the third channel area CA3c may define the channel of the fifth transistor T5 arranged in the third sub-pixel area SPA3.

As the sixth gate pattern GP6 overlaps the fourth channel area CA4c of the third active pattern ACT1c, the gate electrode of the sixth transistor T6 arranged in the third sub-pixel area SPA3 may be defined. In addition, as the sixth gate pattern GP6 overlaps the fourth channel area CA4c of the third active pattern ACT1c, the fourth channel area CA4c may define the channel of the sixth transistor T6 arranged in the third sub-pixel area SPA3.

The first channel length L1 of the first transistor T1 arranged in the first sub-pixel area SPA1 may be defined as a length of the first channel area CA1a in the second direction DR2. In addition, the width W1 of the first transistor T1 arranged in the first sub-pixel area SPA1 may be defined as a length or width of the first channel area CA1a in the first direction DR1.

The second channel length L2 of the first transistor T1 arranged in the second sub-pixel area SPA2 may be defined as a length of the first channel area CA1b in the first direction DR1. In addition, the width W2 of the first transistor T1 arranged in the second sub-pixel area SPA2 may be defined as a length or width of the first channel area CA1b in the second direction DR2.

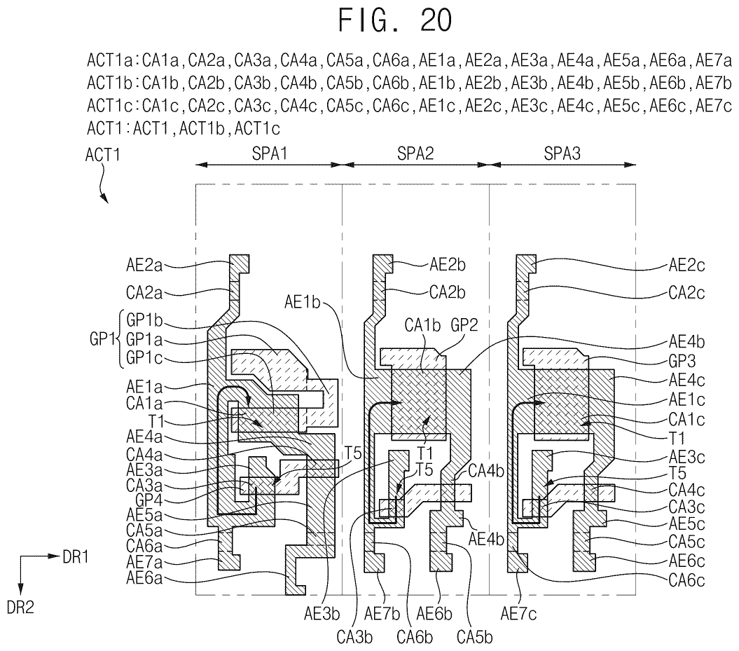

The third channel length L3 of the first transistor T1 arranged in the third sub-pixel area SPA3 may be defined as a length of the first channel area CA1c in the first direction DR1. In addition, the third channel width W3 of the first transistor T1 arranged in the third sub-pixel area SPA3 may be defined as a length or width of the first channel area CA1c in the second direction DR2. A description will be provided below with reference to FIG. 20.

In one or more embodiments, the first channel length L1 of the first transistor T1 arranged in the first sub-pixel area SPA1 may be less than the second channel length L2 of the first transistor T1 arranged in the second sub-pixel area SPA1. In one or more embodiments, the first channel length L1 of the first transistor T1 arranged in the first sub-pixel area SPA1 may be less than the third channel length L3 of the first transistor T1 arranged in the third sub-pixel area SPA3.

In one or more embodiments, the first channel length L1 of the first transistor T1 arranged in the first sub-pixel area SPA1 may be about 8.6 μm or less. For example, the first channel length L1 of the first transistor T1 arranged in the first sub-pixel area SPA1 may be about 3.5 μm or more and may be about 8.6 μm or less. For example, the first channel length L1 of the first transistor T1 arranged in the first sub-pixel area SPA1 may be about 5 μm or more and about 8.6 μm or less.

In one or more embodiments, the first channel width W1 of the first transistor T1 arranged in the first sub-pixel area SPA1 may be less than the second channel width W2 of the first transistor T1 arranged in the second sub-pixel area SPA2. In one or more embodiments, the first channel width W1 of the first transistor T1 arranged in the first sub-pixel area SPA1 may be less than the third channel width W3 of the first transistor T1 arranged in the third sub-pixel area SPA3. However, the channel width of the first transistor T1 arranged in each of the first, second, and third sub-pixel areas SPA1, SPA2, and SPA3 according to embodiments of the disclosure may not be limited thereto. For example, the first channel width W1 of the first transistor T1 arranged in the first sub-pixel area SPA1 may be greater than or equal to each of the second channel width W2 of the first transistor T1 arranged in the second sub-pixel area SPA2 and the third channel width W3 of the first transistor T1 arranged in the third sub-pixel area SPA3.

In one or more embodiments, a width-to-length ratio corresponding to the first channel length L1 and the first channel width W1 of the first transistor T1 arranged in the first sub-pixel area SPA1 may be greater than a width-to-length ratio corresponding to the second channel length L2 and the second channel width W2 of the second transistor T2 arranged in the second sub-pixel area SPA2. In addition, according to one or more embodiments, the width-to-length ratio corresponding to the first channel length L1 and the first channel width W1 of the first transistor T1 arranged in the first sub-pixel area SPA1 may be greater than a width-to-length ratio corresponding to the third channel length L3 and the third channel width W3 of the third transistor T3 arranged in the third sub-pixel area SPA3.

In one or more embodiments, the width-to-length ratio corresponding to the first channel length L1 and the first channel width W1 of the first transistor T1 arranged in the first sub-pixel area SPA1 may be about 1.5 to about 3.7. For example, the width-to-length ratio corresponding to the first channel length L1 and the first channel width W1 of the first transistor T1 arranged in the first sub-pixel area SPA1 may be about 2.6 to about 3.7.

In one or more embodiments, the fourth channel width W4 of the fifth transistor T5 arranged in the first sub-pixel area SPA1 may be greater than the fifth channel width W5 of the fifth transistor T5 arranged in the second sub-pixel area SPA2. In one or more embodiments, the fourth channel width W4 of the fifth transistor T5 arranged in the first sub-pixel area SPA1 may be greater than the sixth channel width W6 of the fifth transistor T5 arranged in the third sub-pixel area SPA3.

In one or more embodiments, a seventh channel width W7 of the sixth transistor T6 arranged in the first sub-pixel area SPA1 may be greater than an eighth channel width W8 of the sixth transistor T6 arranged in the second sub-pixel area SPA2. In one or more embodiments, the seventh channel width W7 of the sixth transistor T6 arranged in the first sub-pixel area SPA1 may be greater than a ninth channel width W9 of the sixth transistor T6 arranged in the third sub-pixel area SPA3.

The second gate-insulating layer GIL2 may be arranged on the first conductive layer CL1. The second gate-insulating layer GIL2 may cover the first conductive layer CL1. The second gate-insulating layer GIL2 may have a substantially uniform thickness following the profile of the first conductive layer CL1. However, the second gate-insulating layer GIL2 according to embodiments of the disclosure may not be limited thereto, and the second gate-insulating layer GIL2 may have a substantially upper surface without forming a step around the first conductive layer CL1. In one or more embodiments, the second gate-insulating layer GIL2 may include an inorganic insulating material.

The second conductive layer CL2 may be arranged on the second gate-insulating layer GIL2. In one or more embodiments, the second conductive layer CL2 may include a conductive material. The second conductive layer CL2 may include a third gate signal line GSL3, a fourth gate signal line GSL4, a fifth gate signal line GSL5, and a seventh gate pattern GP7.

The third gate signal line GSL3 may be arranged across the first, second, and third pixel areas SPA1, SPA2, and SPA3. The third gate signal line GSL3 may extend along the first direction DR1. In one or more embodiments, the third gate signal line GSL3 may not overlap, or may be separated from, the first active layer ACT1 in a plan view.

In one or more embodiments, the third gate signal line GSL3 may overlap the bottom metal layer BML in a plan view. For example, the third gate signal line GSL3 may overlap each of the first, second, and third bottom metal layers BML1, BML2, and BML3 in a plan view. For example, the third gate signal line GSL3 may overlap the first portion BML1a of the first bottom metal layer BML1, the first portion BML2a of the second bottom metal layer BML2, and the first portion BML3a of the third bottom metal layer BML3 in a plan view.

In one or more embodiments, a portion of the third gate signal line GSL3 may protrude toward the second direction DR2 in a plan view. However, a shape of the third gate signal line GSL3 in a plan view according to embodiments of the disclosure may not be limited thereto.

The fourth gate signal line GSL4 may be arranged across the first, second, and third pixel areas SPA1, SPA2, and SPA3. The fourth gate signal line GSL4 may extend along the first direction DR1. In one or more embodiments, the fourth gate signal line GSL4 may be spaced apart from the third gate signal line GSL3 in the second direction DR2.

In one or more embodiments, the fourth gate signal line GSL4 may overlap a portion of the first active layer ACT1 in a plan view. For example, the fourth gate signal line GSL4 may overlap the first area AE1a of the first active pattern ACT1a, the first area AE1b of the second active pattern ACT1b, and the first area AE1c of the third active pattern ACT1c in a plan view.

In one or more embodiments, the fourth gate signal line GSL4 may overlap the bottom metal layer BML in a plan view. For example, the fourth gate signal line GSL4 may overlap each of the first, second, and third bottom metal layers BML1, BML2, and BML3 in a plan view. For example, the fourth gate signal line GSL4 may overlap the first portion BML1a of the first bottom metal layer BML1, the first portion BML2a of the second bottom metal layer BML2, and the first portion BML3a of the third bottom metal layer BML3 in a plan view.

In one or more embodiments, a first portion of the fourth gate signal line GSL4 may protrude toward the second direction DR2 in a plan view. In one or more embodiments, a second portion of the fourth gate signal line GSL4 may protrude in the direction opposite to the second direction DR2 in a plan view. However, a shape of the fourth gate signal line GSL4 in a plan view according to embodiments of the disclosure may not be limited thereto.

The fifth gate signal line GSL5 may be arranged across the first, second, and third pixel areas SPA1, SPA2, and SPA3. The fifth gate signal line GSL5 may extend along the first direction DR1. In one or more embodiments, the fifth gate signal line GSL5 may be spaced apart from the fourth gate signal line GSL4 in the second direction DR2. The fifth gate signal line GSL5 may provide a second initialization voltage VAINT.

In one or more embodiments, the fifth gate signal line GSL5 may overlap a portion of the first active layer ACT1 in a plan view. For example, the fifth gate signal line GSL5 may overlap the sixth area AE6a of the first active pattern ACT1a in a plan view. In one or more embodiments, the fifth gate signal line GSL5 may not overlap the second active pattern ACT1b and the third active pattern ACT1c in a plan view.

In one or more embodiments, the fifth gate signal line GSL5 may overlap the bottom metal layer BML in a plan view. For example, the fifth gate signal line GSL5 may overlap each of the first, second, and third bottom metal layers BML1, BML2, and BML3 in a plan view. For example, the fifth gate signal line GSL5 may overlap the third portion BML1c of the first bottom metal layer BML1, the third portion BML2c of the second bottom metal layer BML2, and the third portion BML3c of the third bottom metal layer BML3 in a plan view.

In one or more embodiments, a portion of the fifth gate signal line GSL5 may protrude in a direction opposite to the second direction DR2 in a plan view. However, a shape of the fifth gate signal line GSL5 in a plan view according to embodiments of the disclosure may not be limited thereto.

The seventh gate pattern GP7 may be arranged between the fourth gate signal line GSL4 and the fifth gate signal line GSL5 in a plan view. The seventh gate pattern GP7 may extend along the first direction DR1.

The seventh gate pattern GP7 may include a first pattern portion GP7a, a second pattern portion GP7b, and a third pattern portion GP7c. The first pattern portion GP7a may be arranged in the first pixel area SPA1, the second pattern portion GP7b may be arranged in the second pixel area SPA2, and the third pattern portion GP7c may be arranged in the third pixel area SPA3. In this disclosure, the first pattern portion GP7a may be referred to as a first upper pattern portion, and the second pattern portion GP7b or the third pattern portion GP7c may be referred to as a second upper pattern portion.

In one or more embodiments, the first pattern portion GP7a, the second pattern portion GP7b, and the third pattern portion GP7c may be integrally formed. The first pattern portion GP7a may define a first hole exposing a portion of the first conductive layer CL1. The second pattern portion GP7b may define a second hole exposing a portion of the first conductive layer CL1. The third pattern portion GP7c may define a third hole exposing a portion of the first conductive layer CL1.

The first pattern portion GP7a of the seventh gate pattern GP7 may overlap the first gate pattern GP1 in a plan view. For example, the first pattern portion GP7a may overlap the entire first gate pattern GP1 in a plan view. For example, the first pattern portion GP7a may overlap each of the first portion GP1a, the second portion GP1c, and the connecting portion GP1b of the first gate pattern GP1 in a plan view. The first hole of the first pattern portion GP7a may expose a portion of the upper surface of the first portion GP1a of the first gate pattern GP1.

In one or more embodiments, the first pattern portion GP7a of the seventh gate pattern GP7 may correspond to the first electrode of the first capacitor C1 connected to the gate terminal of the first transistor T1 arranged in the first sub-pixel area SPA1. In one or more embodiments, the first gate pattern GP1 may correspond to the second electrode opposite to the first electrode of the first capacitor C1 connected to the gate terminal of the first transistor T1 arranged in the first sub-pixel area SPA1.

The second pattern portion GP7b of the seventh gate pattern GP7 may overlap the second gate pattern GP2 in a plan view. For example, the second pattern portion GP7b may overlap the entire second gate pattern GP2 in a plan view. The second hole of the second pattern portion GP7b may expose a portion of the upper surface of the second gate pattern GP2.

In one or more embodiments, the second pattern portion GP7b of the seventh gate pattern GP7 may be the first electrode of the first capacitor C1 connected to the gate terminal of the first transistor T1 arranged in the second sub-pixel area SPA2. In one or more embodiments, the second gate pattern GP2 may be the second electrode opposite to the first electrode of the first capacitor C1 connected to the gate terminal of the first transistor T1 arranged in the second sub-pixel area SPA2.

The third pattern portion GP7c of the seventh gate pattern GP7 may overlap the third gate pattern GP3 in a plan view. For example, the third pattern portion GP7c may overlap the entire third gate pattern GP3 in a plan view. The third hole of the third pattern portion GP7c may expose a portion of the upper surface of the third gate pattern GP3.

In one or more embodiments, the third pattern portion GP7c of the seventh gate pattern GP7 may be the first electrode of the first capacitor C1 connected to the gate terminal of the first transistor T1 arranged in the third sub-pixel area SPA3. In one or more embodiments, the third gate pattern GP3 may be the second electrode opposite to the first electrode of the first capacitor C1 connected to the gate terminal of the first transistor T1 arranged in the third sub-pixel area SPA3.

In the disclosure, the first capacitor C1 connected to the gate terminal of the first transistor T1 arranged in the first sub-pixel area SPA1 may be referred to as a first storage capacitor, and the first capacitor C1 connected to the gate terminal of the first transistor T1 arranged in the second sub-pixel area SPA2 or the third sub-pixel area SPA3 may be referred to as a second storage capacitor.

In one or more embodiments, an area of a portion of the seventh gate pattern GP7 where the first pattern portion GP7a overlaps the first gate pattern GP1 in a plan view may be greater than an area of a portion of the seventh gate pattern GP7 where the second pattern portion GP7b overlaps the second gate pattern GP2. In one or more embodiments, the area of the portion of the seventh gate pattern GP7 where the first pattern portion GP7a overlaps the first gate pattern GP1 may be greater than an area of the portion of the seventh gate pattern GP7 where the third pattern portion GP7c overlaps the third gate pattern GP3. Accordingly, a capacitance of the first capacitor C1 connected to the gate terminal of the first transistor T1 arranged in the first sub-pixel area SPA1 may be greater than the capacitance of the first capacitor C1 connected to the gate terminal of the first transistor T1 arranged in the second sub-pixel area SPA2 or the third sub-pixel area SPA3.

A first interlayer insulating layer ISL1 may be arranged on the second conductive layer CL2. The first interlayer insulating layer ISL1 may cover the second conductive layer CL2. The first interlayer insulating layer ISL1 may have a substantially uniform thickness following the profile of the second conductive layer CL2. However, the first interlayer insulating layer ISL1 according to embodiments of the disclosure may not be limited thereto, and the first interlayer insulating layer ISL1 may have a substantially upper surface without forming a step around the second conductive layer CL2. In one or more embodiments, the first interlayer insulating layer ISL1 may include an inorganic insulating material.

The second active layer ACT2 may be arranged on the first interlayer insulating layer ISL1. In one or more embodiments, the second active layer ACT2 may include an oxide semiconductor. However, the material included in the second active layer ACT2 according to embodiments of the disclosure may not be limited thereto, and the second active layer ACT2 may include various materials, such as amorphous silicon, silicon semiconductors, and/or organic semiconductors.

In addition, a type of dopant doped into the second active layer ACT2 according to embodiments of the disclosure may not be limited thereto, and the dopant doped into the second active layer ACT2 may be a P-type dopant.

In the disclosure, the third transistor T3 arranged in the first sub-pixel area SPA1 may be referred to as a first compensation transistor, and the third transistor T3 arranged in the second sub-pixel area SPA2 or the third sub-pixel area SPA3 may be referred to as a second compensation transistor. In one or more embodiments, the first compensation transistor and the second compensation transistor may be NMOS transistors. In one or more embodiments, the first compensation transistor and the second compensation transistor may be PMOS transistors.

The second active layer ACT2 may include a fourth active pattern ACT2a arranged in the first sub-pixel area SPA1, a fifth active pattern ACT2b arranged in the second sub-pixel area SPA2, and a sixth active pattern ACT2c arranged in the third sub-pixel area SPA3. In one or more embodiments, each of the fourth, fifth, and sixth active patterns ACT2a, ACT2b, and ACT2c may be spaced apart from each other in the first direction DR1.

The fourth active pattern ACT2a may include an eighth area AE8a, a ninth area AE9a, a tenth area AE10a, a seventh channel area CA7a, and an eighth channel area CA8a. In one or more embodiments, the eighth, ninth, and tenth areas AE8a, AE9a, and AE10a may be doping areas doped with N-type dopants. The seventh and eighth channel areas CA7a and CA8a may be doped with a lower concentration than the above doping areas, or may be non-doped areas.

The fifth active pattern ACT2b may include an eighth area AE8b, a ninth area AE9b, a tenth area AE10b, a seventh channel area CA7b, and an eighth channel area CA8b. In one or more embodiments, the eighth, ninth, and tenth areas AE8b, AE9b, and AE10b may be doping areas doped with N-type dopants. The seventh and eighth channel areas CA7b and CA8b may be doped with a lower concentration than the above doping areas, or may be non-doped areas. Hereinafter, the description of the fifth active pattern ACT2b that overlaps the description of the fourth active pattern ACT2a may be omitted or briefly described.

The sixth active pattern ACT2c may include an eighth area AE8c, a ninth area AE9c, a tenth area AE10c, a seventh channel area CA7c, and an eighth channel area CA8c. In one or more embodiments, the eighth, ninth, and tenth areas AE8c, AE9c, and AE10c may be doping areas doped with N-type dopants. The seventh and eighth channel areas CA7c and CA8c may be doped with a lower concentration than the above doping areas, or may be non-doped areas. Hereinafter, the description of the sixth active pattern ACT2c that overlaps the description of the fifth active pattern ACT2b may be omitted or briefly described.

In one or more embodiments, shapes of the fourth, fifth, and sixth active patterns ACT2a, ACT2b, and ACT2c may be substantially a same, in a plan view. In the fourth active pattern ACT2a, the eighth area AE8a may be adjacent to each of the seventh and eighth channel areas CA7a and CA8a.

The seventh channel area CA7a of the fourth active pattern ACT2a may correspond to the channel of the fourth transistor T4 arranged in the first sub-pixel area SPA1. The seventh channel area CA7b of the fifth active pattern ACT2b may correspond to the channel of the fourth transistor T4 arranged in the second sub-pixel area SPA2. The seventh channel area CA7c of the sixth active pattern ACT2c may correspond to the channel of the fourth transistor T4 arranged in the third sub-pixel area SPA3.

The eighth channel area CA8a of the fourth active pattern ACT2a may correspond to the channel of the third transistor T3 arranged in the first sub-pixel area SPA1. The eighth channel area CA8b of the fifth active pattern ACT2b may correspond to the channel of the third transistor T3 arranged in the second sub-pixel area SPA2. The eighth channel area CA8c of the sixth active pattern ACT2c may correspond to the channel of the third transistor T3 arranged in the third sub-pixel area SPA3.

The second active layer ACT2 may be spaced apart from the first active layer ACT1 in a plan view. For example, in the first pixel area SPA1, the fourth active pattern ACT2a may be spaced apart from the first active pattern ACT1a in a plan view. For example, in the second pixel area SPA2, the fifth active pattern ACT2b may be spaced apart from the second active pattern ACT1b in a plan view. For example, in the third pixel area SPA3, the sixth active pattern ACT2c may be spaced apart from the third active pattern ACT1c in a plan view.

The second active layer ACT2 may overlap the third gate signal line GSL3 and the fourth gate signal line GSL4 in a plan view. For example, the seventh channel area CA7a of the fourth active pattern ACT2a may overlap the third gate signal line GSL3 in a plan view, and the eighth channel area CA8a of the fourth active pattern ACT2a may overlap the fourth gate signal line GSL4 in a plan view. For example, the seventh channel area CA7b of the fifth active pattern ACT2b may overlap the third gate signal line GSL3 in a plan view, and the eighth channel area CA8b of the fifth active pattern ACT2b may overlap the fourth gate signal line GSL4 in a plan view. For example, the seventh channel area CA7c of the sixth active pattern ACT2c may overlap the third gate signal line GSL3 in a plan view, and the eighth channel area CA8c of the sixth active pattern ACT2c may overlap the fourth gate signal line GSL4 in a plan view.

The third gate-insulating layer GIL3 may be arranged on the second active layer ACT2. The third gate-insulating layer GIL3 may cover the second active layer ACT2. The third gate-insulating layer GIL3 may have a substantially uniform thickness following the profile of the second active layer ACT2. However, the third gate-insulating layer GIL3 according to embodiments of the disclosure may not be limited thereto, and the third gate-insulating layer GIL3 may have a substantially upper surface without forming a step around the second active layer ACT2. In one or more embodiments, the third gate-insulating layer GIL3 may include an inorganic insulating material.

The third conductive layer CL3 may be arranged on the third gate-insulating layer GIL3. In one or more embodiments, the third conductive layer CL3 may include a conductive material. The third conductive layer CL3 may include a sixth gate signal line GSL6, a seventh gate signal line GSL7, and an eighth gate signal line GSL8.

Each of the sixth gate signal line GSL6, the seventh gate signal line GSL7, and the eighth gate signal line GSL8 may be arranged across the first, second, and third sub-pixel areas SPA1, SPA2, and SPA3.

The sixth gate signal line GSL6 may extend along the first direction DR1. In one or more embodiments, a portion of the sixth gate signal line GSL6 may protrude toward the second direction DR2 in a plan view. However, a shape of the sixth gate signal line GSL6 in a plan view according to embodiments of the disclosure may not be limited thereto.

The gate initialization signal GI may be applied to the sixth gate signal line GSL6. In one or more embodiments, the sixth gate signal line GSL6 may overlap the second active layer ACT2 in a plan view. For example, the sixth gate signal line GSL6 may overlap each of the seventh channel area CA7a of the fourth active pattern ACT2a, the seventh channel area CA7b of the fifth active pattern ACT2b, and the seventh channel area CA7c of the sixth active pattern ACT2c. Accordingly, the sixth gate signal line GSL6 may define the gate electrode of the fourth transistor T4 arranged in each of the first, second, and third sub-pixel areas SPA1, SPA2, and SPA3. In addition, the seventh channel area CA7a of the fourth active pattern ACT2a may define the channel of the fourth transistor T4 arranged in the first sub-pixel area SPA1. The seventh channel area CA7b of the fifth active pattern ACT2b may define the channel of the fourth transistor T4 arranged in the second sub-pixel area SPA2. The seventh channel area CA7c of the sixth active pattern ACT2c may define the channel of the fourth transistor T4 arranged in the third sub-pixel area SPA3.

The seventh gate signal line GSL7 may extend along the first direction DR1. In one or more embodiments, the seventh gate signal line GSL7 may be spaced apart from the sixth gate signal line GSL6 in the second direction DR2. In one or more embodiments, a portion of the seventh gate signal line GSL7 may protrude toward the second direction DR2 in a plan view. However, a shape of the seventh gate signal line GSL7 in a plan view according to embodiments of the disclosure may not be limited thereto.

The compensation signal GC may be applied to the seventh gate signal line GSL7. In one or more embodiments, the seventh gate signal line GSL7 may overlap the second active layer ACT2 in a plan view. For example, the seventh gate signal line GSL7 may overlap each of the eighth channel area CA8a of the fourth active pattern ACT2a, the eighth channel area CA8b of the fifth active pattern ACT2b, and the eighth channel area CA8c of the sixth active pattern ACT2c. Accordingly, the seventh gate signal line GSL7 may define the gate electrode of the third transistor T3 arranged in each of the first, second, and third sub-pixel areas SPA1, SPA2, and SPA3. In addition, the eighth channel area CA8a of the fourth active pattern ACT2a may define the channel of the third transistor T3 arranged in the first sub-pixel area SPA1. The eighth channel area CA8b of the fifth active pattern ACT2b may define the channel of the third transistor T3 arranged in the second sub-pixel area SPA2. The eighth channel area CA8c of the sixth active pattern ACT2c may define the channel of the third transistor T3 arranged in the third sub-pixel area SPA3.

The eighth gate signal line GSL8 may extend along the first direction DR1. In one or more embodiments, the eighth gate signal line GSL8 may be spaced apart from the seventh gate signal line GSL7 in the second direction DR2. In one or more embodiments, a portion of the eighth gate signal line GSL8 may protrude toward the second direction DR2 in a plan view. However, a shape of the eighth gate signal line GSL8 in a plan view according to embodiments of the disclosure may not be limited thereto. The eighth gate signal line GSL8 may overlap the second gate signal line GSL2 in a plan view. The eighth gate signal line GSL8 may provide a bias voltage VOBS.

The second interlayer insulating layer ISL2 may be arranged on the third conductive layer CL3. The second interlayer insulating layer ISL2 may have a substantially upper surface. However, the second interlayer insulating layer ISL2 according to embodiments of the disclosure may not be limited thereto, and the second interlayer insulating layer ISL2 may have a substantially uniform thickness while forming a step around the third conductive layer CL3. In one or more embodiments, the second interlayer insulating layer ISL2 may include an organic insulating material and/or an inorganic insulating material.

The fourth conductive layer CL4 may be arranged on the second interlayer insulating layer ISL2. In one or more embodiments, the fourth conductive layer CL4 may include a conductive material. The fourth conductive layer CL4 may define a first contact hole CNT1 (e.g., first contact holes) to be connected with lower components (e.g., the bottom metal layer BML, the first active layer ACT1, the first conductive layer CL1, the second conductive layer CL2, the second active layer ACT2, and the third conductive layer CL3). The first contact hole CNT1 may be a hole penetrating in a thickness direction (e.g., a third direction DR3) through at least one of a barrier layer BAR, a buffer layer BUF, the first gate-insulating layer GIL1, the second gate-insulating layer GIL2, the first interlayer insulating layer ISL1, or the third gate-insulating layer GIL3.

The fourth conductive layer CL4 may include a horizontal voltage line HVL, a first horizontal signal line HSL1, a second horizontal signal line HSL2, a first connecting electrode CNE1, a second connecting electrode CNE2, a third connecting electrode CNE3, a fourth connecting electrode CNE4, a fifth connecting electrode CNE5, a sixth connecting electrode CNE6, a seventh connecting electrode CNE7, an eighth connecting electrode CNE8, a ninth connecting electrode CNE9, a tenth connecting electrode CNE10, an eleventh connecting electrode CNE11, a twelfth connecting electrode CNE12, a thirteenth connecting electrode CNE13, a fourteenth connecting electrode CNE14, a fifteenth connecting electrode CNE15, a sixteenth connecting electrode CNE16, a seventeenth connecting electrode CNE17, an eighteenth connecting electrode CNE18, a nineteenth connecting electrode CNE19, a twentieth connecting electrode CNE20, and a twenty-first connecting electrode CNE21.

The horizontal voltage line HVL may be arranged across the first, second, and third sub-pixel areas SPA1 to SPA3. The horizontal voltage line HVL may extend along the first direction DR1. A first initialization voltage VINT may be applied to the horizontal voltage line HVL. Accordingly, the horizontal voltage line HVL may correspond to the first initialization voltage line.

In one or more embodiments, the horizontal voltage line HVL may overlap the ninth area AE9a of the fourth active pattern ACT4a in a plan view. For example, the horizontal voltage line HVL may be electrically connected to the ninth area AE9a of the fourth active pattern ACT4a through the first contact hole CNT1. For example, the horizontal voltage line HVL may contact the ninth area AE9a of the fourth active pattern ACT4a through the first contact hole CNT1. The ninth area AE9a of the fourth active pattern ACT4a may correspond to the second terminal of the fourth transistor T4 arranged in the first sub-area SPA1.

In one or more embodiments, the horizontal voltage line HVL may overlap the ninth area AE9b of the fifth active pattern ACT4b in a plan view. For example, the horizontal voltage line HVL may be electrically connected to the ninth area AE9b of the fifth active pattern ACT4b through the first contact hole CNT1. For example, the horizontal voltage line HVL may contact the ninth area AE9b of the fifth active pattern ACT4b through the first contact hole CNT1. The ninth area AE9b of the fifth active pattern ACT4b may correspond to the second terminal of the fourth transistor T4 arranged in the second sub-area SPA2.

In one or more embodiments, the horizontal voltage line HVL may overlap the ninth area AE9c of the sixth active pattern ACT4c in a plan view. For example, the horizontal voltage line HVL may be electrically connected to the ninth area AE9c of the sixth active pattern ACT4c through the first contact hole CNT1. For example, the horizontal voltage line HVL may contact the ninth area AE9c of the sixth active pattern ACT4c through the first contact hole CNT1. The ninth area AE9c of the sixth active pattern ACT4c may correspond to the second terminal of the fourth transistor T4 arranged in the third sub-area SPA3.

The first horizontal signal line HSL1 may be arranged across the first, second, and third sub-pixel areas SPA1, SPA2, and SPA3. The first horizontal signal line HSL1 may extend along the first direction DR1. In one or more embodiments, the first horizontal signal line HSL1 may have a planar shape alternating between convex portions in the second direction DR2 and concave portions in the opposite direction of the second direction DR2.

The first horizontal signal line HSL1 may provide a light-emitting signal EM for the first sub-pixel SPX1. For example, the first horizontal signal line HSL1 may provide a light-emitting signal EM to be received by the gate terminal of the fifth transistor T5 arranged in the first sub-pixel area SPA1. In other words, the first horizontal signal line HSL1 may be connected to the gate terminal of the fifth transistor T5 arranged in the first sub-pixel area SPA1.

In one or more embodiments, the first horizontal signal line HSL1 may overlap the fourth gate pattern GP4 in a plan view. For example, the first horizontal signal line HSL1 may contact the fourth gate pattern GP4 through the first contact hole CNT1. Accordingly, the first horizontal signal line HSL1 may provide the light-emitting signal EM for the first sub-pixel SPX1 to the gate terminal of the fifth transistor T5 arranged in the first sub-pixel area SPA1.

The second horizontal signal line HSL2 may be arranged across the first, second, and third sub-pixel areas SPA1, SPA2, and SPA3. The second horizontal signal line HSL2 may extend along the first direction DR1. In one or more embodiments, the second horizontal signal line HSL2 may have a planar shape alternating between convex portions in the second direction DR2 and concave portions in the opposite direction of the second direction DR2.

The second horizontal signal line HSL2 may provide light-emitting signals EM for each of the second sub-pixel SPX2 and the third sub-pixel SPX3. For example, the second horizontal signal line HSL2 may provide a light-emitting signal EM to be received by the gate terminal of the fifth transistor T5 arranged in each of the second sub-pixel area SPA2 and the third sub-pixel area SPA3. In other words, the second horizontal signal line HSL2 may be connected to the gate terminal of the fifth transistor T5 arranged in the second sub-pixel area SPA2. In addition, the second horizontal signal line HSL2 may be connected to the gate terminal of the fifth transistor T5 arranged in the third sub-pixel area SPA3.

In one or more embodiments, the second horizontal signal line HSL2 may overlap each of the fifth gate pattern GP5 and the sixth gate pattern GP6 in a plan view. For example, the second horizontal signal line HSL2 may contact each of the fifth gate pattern GP5 and the sixth gate pattern GP6 through the first contact hole CNT1. Accordingly, the second horizontal signal line HSL2 may provide the light-emitting signals EM for each of the second sub-pixel SPX2 and the third sub-pixel SPX3 to the gate terminal of the fifth transistor T5 arranged in each of the second sub-pixel area SPA2 and the third sub-pixel area SPA3.

The first connecting electrode CNE1 may be arranged in the first sub-pixel area SPA1. In one or more embodiments, the first connecting electrode CNE1 may overlap the first portion GP1a of the first gate pattern GP1 in a plan view. In one or more embodiments, the first connecting electrode CNE1 may overlap the eighth area AE8a of the fourth active pattern ACT2a in a plan view. For example, the first connecting electrode CNE1 may contact the first portion GP1a of the first gate pattern GP1 through the first contact hole CNT1 and the first hole. In addition, the first connecting electrode CNE1 may contact the eighth area AE8a of the fourth active pattern ACT2a through the first contact hole CNT1. Accordingly, in the first sub-pixel area SPA1, the first connecting electrode CNE1 may electrically connect the second terminal of the third transistor T3, the first terminal of the fourth transistor T4, and the gate terminal of the first transistor T1 to one another.

In one or more embodiments, the first connecting electrode CNE1 may overlap a portion of the first gate signal line GSL1. Accordingly, in the first sub-pixel area SPA1, the portion of the first connecting electrode CNE1 that overlaps the first gate signal line GSL1 may correspond to the third electrode of the second capacitor C2. Also, in the first sub-pixel area SPA1, the portion of the first connecting electrode CNE1 that overlaps the first gate signal line GSL1 may correspond to the fourth electrode of the second capacitor C2.

The second connecting electrode CNE2 may be arranged in the second sub-pixel area SPA2. In one or more embodiments, the second connecting electrode CNE2 may be spaced apart from the first connecting electrode CNE1 in the first direction DR1.

In one or more embodiments, the second connecting electrode CNE2 may overlap the second gate pattern GP2 in a plan view. In one or more embodiments, the second connecting electrode CNE2 may overlap the eighth area AE8b of the fifth active pattern ACT2b in a plan view. For example, the second connecting electrode CNE2 may contact the second gate pattern GP2 through the first contact hole CNT1 and the second hole. In addition, the second connecting electrode CNE2 may contact the eighth area AE8b of the fifth active pattern ACT2b through the first contact hole CNT1. Accordingly, in the second sub-pixel area SPA2, the second connecting electrode CNE2 may electrically connect the second terminal of the third transistor T3, the first terminal of the fourth transistor T4, and the gate terminal of the first transistor T1.

In one or more embodiments, the second connecting electrode CNE2 may overlap a portion of the first gate line GSL1. Accordingly, in the second sub-pixel area SPA2, the portion where the second connecting electrode CNE2 overlaps the first gate line GSL1 may correspond to the third electrode of the second capacitor C2. In addition, in the second sub-pixel area SPA2, the portion where the second connecting electrode CNE2 overlaps the first gate line GSL1 may correspond to the fourth electrode of the second capacitor C2.

The third connecting electrode CNE3 may be arranged in the third sub-pixel area SPA3. In one or more embodiments, the third connecting electrode CNE3 may be spaced apart from the second connecting electrode CNE2 in the first direction DR1.

In one or more embodiments, the third connecting electrode CNE3 may overlap the third gate pattern GP3 in a plan view. In one or more embodiments, the third connecting electrode CNE3 may overlap the eighth area AE8c of the sixth active pattern ACT2c in a plan view. For example, the third connecting electrode CNE3 may contact the third gate pattern GP3 through the first contact hole CNT1 and the third hole. In addition, the third connecting electrode CNE3 may contact the eighth area AE8c of the sixth active pattern ACT2c through the first contact hole CNT1. Accordingly, in the third sub-pixel area SPA3, the third connecting electrode CNE3 may electrically connect the second terminal of the third transistor T3, the first terminal of the fourth transistor T4, and the gate terminal of the first transistor T1.

In one or more embodiments, the third connecting electrode CNE3 may overlap a portion of the first gate line GSL1. Accordingly, in the third sub-pixel area SPA3, the portion where the third connecting electrode CNE3 overlaps the first gate line GSL1 may correspond to the third electrode of the second capacitor C2. In addition, in the third sub-pixel area SPA3, the portion where the third connecting electrode CNE3 overlaps the first gate line GSL1 may correspond to the fourth electrode of the second capacitor C2.

The fourth connecting electrode CNE4 may be arranged in the first sub-pixel area SPA1. In one or more embodiments, the fourth connecting electrode CNE4 may be spaced apart from the first connecting electrode CNE1 in a plan view. The fourth connecting electrode CNE4 may correspond to the first terminal of the second transistor T2 arranged in the first sub-pixel area SPA1.

In one or more embodiments, the fourth connecting electrode CNE4 may overlap the second area AE2a of the first active pattern ACT1a in a plan view. For example, the fourth connecting electrode CNE4 may contact the second area AE2a of the first active pattern ACT1a through the first contact hole CNT1.

The fifth connecting electrode CNE5 may be arranged in the second sub-pixel area SPA2. In one or more embodiments, the fifth connecting electrode CNE5 may be spaced apart from the second connecting electrode CNE2 in a plan view. In one or more embodiments, the fifth connecting electrode CNE5 may be spaced apart from the fourth connecting electrode CNE4 in the first direction DR1. The fifth connecting electrode CNE5 may correspond to the first terminal of the second transistor T2 arranged in the second sub-pixel area SPA2.

In one or more embodiments, the fifth connecting electrode CNE5 may overlap the second area AE2b of the second active pattern ACT1b in a plan view. For example, the fifth connecting electrode CNE5 may contact the second area AE2b of the second active pattern ACT1b through the first contact hole CNT1.

The sixth connecting electrode CNE6 may be arranged in the third sub-pixel area SPA3. In one or more embodiments, the sixth connecting electrode CNE6 may be spaced apart from the third connecting electrode CNE3 in a plan view. In one or more embodiments, the sixth connecting electrode CNE6 may be spaced apart from the fifth connecting electrode CNE5 in the first direction DR1. The sixth connecting electrode CNE6 may correspond to the first terminal of the second transistor T2 arranged in the third sub-pixel area SPA3.

In one or more embodiments, the sixth connecting electrode CNE6 may overlap the second area AE2c of the third active pattern ACT1c in a plan view. For example, the sixth connecting electrode CNE6 may contact the second area AE2c of the third active pattern ACT1c through the first contact hole CNT1.

The seventh connecting electrode CNE7 may be arranged in the first sub-pixel area SPA1. In one or more embodiments, the seventh connecting electrode CNE7 may be spaced apart from the first connecting electrode CNE1 in the first direction DR1. In one or more embodiments, the seventh connecting electrode CNE7 may overlap the connecting portion GP1b of the first gate pattern GP1 in a plan view. In one or more embodiments, the seventh connecting electrode CNE7 may be spaced apart from each of the first portion GP1a and the second portion GP1c of the first gate pattern GP1 in a plan view.

In one or more embodiments, the seventh connecting electrode CNE7 may overlap the fourth area AE4a of the first active pattern ACT1a in a plan view. In one or more embodiments, the seventh connecting electrode CNE7 may overlap the tenth area AE10a of the fourth active pattern ACT2a in a plan view. For example, the seventh connecting electrode CNE7 may contact the fourth area AE4a of the first active pattern ACT1a and the tenth area AE10a of the fourth active pattern ACT2a through the first contact hole CNT1. Accordingly, the seventh connecting electrode CNE7 may electrically connect the fourth area AE4a of the first active pattern ACT1a and the tenth area AE10a of the fourth active pattern ACT2a through the first contact hole CNT1.

In the first sub-pixel area SPA1, the seventh connecting electrode CNE7 may correspond to each of the first terminal of the first transistor T1, the first terminal of the third transistor T3, and the first terminal of the sixth transistor T6. In other words, the seventh connecting electrode CNE7 may correspond to the second node N2 connected to each of the first transistor T1, the third transistor T3, and the sixth transistor T6 in the first sub-pixel area SPA1.

The eighth connecting electrode CNE8 may be arranged in the second sub-pixel area SPA2. In one or more embodiments, the eighth connecting electrode CNE8 may be spaced apart from the second connecting electrode CNE2 in the first direction DR1. In one or more embodiments, the eighth connecting electrode CNE8 may overlap a portion of the second gate pattern GP2 in a plan view.

In one or more embodiments, the eighth connecting electrode CNE8 may overlap the fourth area AE4b of the second active pattern ACT1b in a plan view. In one or more embodiments, the eighth connecting electrode CNE8 may overlap the tenth area AE10b of the fifth active pattern ACT2b in a plan view. For example, the eighth connecting electrode CNE8 may contact the fourth area AE4b of the second active pattern ACT1b and the tenth area AE10b of the fifth active pattern ACT2b through the first contact hole CNT1. Accordingly, the eighth connecting electrode CNE8 may electrically connect the fourth area AE4b of the second active pattern ACT1b and the tenth area AE10b of the fifth active pattern ACT2b through the first contact hole CNT1.

In the second sub-pixel area SPA2, the eighth connecting electrode CNE8 may correspond to each of the first terminal of the first transistor T1, the first terminal of the third transistor T3, and the first terminal of the sixth transistor T6. In other words, the eighth connecting electrode CNE8 may correspond to the second node N2 connected to each of the first transistor T1, the third transistor T3, and the sixth transistor T6 in the second sub-pixel area SPA2.

The ninth connecting electrode CNE9 may be arranged in the third sub-pixel area SPA3. In one or more embodiments, the eighth connecting electrode CNE8 may be spaced apart from the third connecting electrode CNE3 in the first direction DR1. In one or more embodiments, the ninth connecting electrode CNE9 may overlap a portion of the third gate pattern GP3 in a plan view.

In one or more embodiments, the ninth connecting electrode CNE9 may overlap the fourth area AE4c of the third active pattern ACT1c in a plan view. In one or more embodiments, the ninth connecting electrode CNE9 may overlap the tenth area AE10c of the sixth active pattern ACT2c in a plan view. For example, the ninth connecting electrode CNE9 may contact the fourth area AE4c of the third active pattern ACT1c and the tenth area AE10c of the sixth active pattern ACT2c through the first contact hole CNT1. Accordingly, the ninth connecting electrode CNE9 may electrically connect the fourth area AE4c of the third active pattern ACT1c and the tenth area AE10c of the sixth active pattern ACT2c to each other through the first contact hole CNT1.

In the third sub-pixel area SPA3, the ninth connecting electrode CNE9 may correspond to the first terminal of the first transistor T1, the first terminal of the third transistor T3, and the first terminal of the sixth transistor T6. In other words, the ninth connecting electrode CNE9 may correspond to a second node N2 connected to each of the first transistor T1, the third transistor T3, and the sixth transistor T6 in the third sub-pixel area SPA3.

The tenth connecting electrode CNE10 may be arranged in the first sub-pixel area SPA1. In one or more embodiments, the tenth connecting electrode CNE10 may be spaced apart from the first connecting electrode CNE1 in the second direction DR2. In one or more embodiments, the tenth connecting electrode CNE10 may be spaced apart from the seventh connecting electrode CNE7 in a direction opposite to the first direction DR1.

In one or more embodiments, the tenth connecting electrode CNE10 may overlap the third area AE3a of the first active pattern ACT1a and the first pattern portion GP7a of the seventh gate pattern GP7 in a plan view. For example, the tenth connecting electrode CNE10 may contact the third area AE3a of the first active pattern ACT1a and the first pattern portion GP7a of the seventh gate pattern GP7 through the first contact hole CNT1. Accordingly, the tenth connecting electrode CNE10 may electrically connect the third area AE3a of the first active pattern ACT1a and the first pattern portion GP7a of the seventh gate pattern GP7 to each other.

The eleventh connecting electrode CNE11 may be arranged in the second sub-pixel area SPA2. In one or more embodiments, the eleventh connecting electrode CNE11 may be spaced apart from the second connecting electrode CNE2 in the second direction DR2. In one or more embodiments, the eleventh connecting electrode CNE11 may be spaced apart from the eighth connecting electrode CNE8 in a direction opposite to the first direction DR1.

In one or more embodiments, the eleventh connecting electrode CNE11 may overlap the third area AE3b of the second active pattern ACT1b and the second pattern portion GP7b of the seventh gate pattern GP7 in a plan view. For example, the eleventh connecting electrode CNE11 may contact the third area AE3b of the second active pattern ACT1b and the second pattern portion GP7b of the seventh gate pattern GP7 through the first contact hole CNT1. Accordingly, the eleventh connecting electrode CNE11 may electrically connect the third area AE3b of the second active pattern ACT1b and the second pattern portion GP7b of the seventh gate pattern GP7 to each other.

The twelfth connecting electrode CNE12 may be arranged in the third sub-pixel area SPA3. In one or more embodiments, the twelfth connecting electrode CNE12 may be spaced apart from the third connecting electrode CNE3 in the second direction DR2. In one or more embodiments, the twelfth connecting electrode CNE12 may be spaced apart from the ninth connecting electrode CNE9 in a direction opposite to the first direction DR1.

In one or more embodiments, the twelfth connecting electrode CNE12 may overlap the third area AE3b of the third active pattern ACT1c and the third pattern portion GP7c of the seventh gate pattern GP7 in a plan view. For example, the twelfth connecting electrode CNE12 may contact the third area AE3b of the third active pattern ACT1c and the third pattern portion GP7c of the seventh gate pattern GP7 through the first contact hole CNT1. Accordingly, the twelfth connecting electrode CNE12 may electrically connect the third area AE3b of the third active pattern ACT1c and the third pattern portion GP7c of the seventh gate pattern GP7 to each other.

The thirteenth connecting electrode CNE13 may be arranged in the first sub-pixel area SPA1. In one or more embodiments, the thirteenth connecting electrode CNE13 may be spaced apart from the second horizontal signal line HSL2 in the second direction DR2.

In one or more embodiments, the thirteenth connecting electrode CNE13 may overlap the fifth area AE5a of the first active pattern ACT1a in a plan view. For example, the thirteenth connecting electrode CNE13 may contact the fifth area AE5a of the first active pattern ACT1a through the first contact hole CNT1. In the first sub-pixel area SPA1, the thirteenth connecting electrode CNE13 may correspond to the second terminal of the sixth transistor T6 and the second terminal of the seventh transistor T7.

The fourteenth connecting electrode CNE14 may be arranged in the second sub-pixel area SPA2. In one or more embodiments, the fourteenth connecting electrode CNE14 may be spaced apart from the second horizontal signal line HSL2 in the second direction DR2. In one or more embodiments, the fourteenth connecting electrode CNE14 may be spaced apart from the thirteenth connecting electrode CNE13 in the first direction DR1.

In one or more embodiments, the fourteenth connecting electrode CNE14 may overlap the fifth area AE5b of the second active pattern ACT1b in a plan view. For example, the fourteenth connecting electrode CNE14 may contact the fifth area AE5b of the second active pattern ACT1b through the first contact hole CNT1. In the second sub-pixel area SPA2, the thirteenth connecting electrode CNE13 may correspond to the second terminal of the sixth transistor T6 and the second terminal of the seventh transistor T7.

The fifteenth connecting electrode CNE15 may be arranged in the third sub-pixel area SPA3. In one or more embodiments, the fifteenth connecting electrode CNE15 may be spaced apart from the second horizontal signal line HSL2 in the second direction DR2. In one or more embodiments, the fifteenth connecting electrode CNE15 may be spaced apart from the fourteenth connecting electrode CNE14 in the first direction DR1.

In one or more embodiments, the fifteenth connecting electrode CNE15 may overlap the fifth area AE5c of the third active pattern ACT1c in a plan view. For example, the fifteenth connecting electrode CNE15 may contact the fifth area AE5c of the third active pattern ACT1c through the first contact hole CNT1. In the third sub-pixel area SPA3, the fifteenth connecting electrode CNE15 may correspond to the second terminal of the sixth transistor T6 and the second terminal of the seventh transistor T7.

The sixteenth connecting electrode CNE16 may be arranged in the first sub-pixel area SPA1. In one or more embodiments, the sixteenth connecting electrode CNE16 may be spaced apart from the thirteenth connecting electrode CNE13 in the second direction DR2.

In one or more embodiments, the sixteenth connecting electrode CNE16 may overlap the sixth area AE6a of the first active pattern ACT1a and the fifth gate signal line GSL5 in a plan view. For example, the sixteenth connecting electrode CNE16 may contact the sixth area AE6a of the first active pattern ACT1a and the fifth gate signal line GSL5 through the first contact hole CNT1. In the first sub-pixel area SPA1, the sixteenth connecting electrode CNE16 may correspond to the first terminal of the seventh transistor T7. Accordingly, the second initialization voltage VAINT may be supplied to the first terminal of the seventh transistor T7 arranged in the first sub-pixel area SPA1.

The seventeenth connecting electrode CNE17 may be arranged in the second sub-pixel area SPA2. In one or more embodiments, the seventeenth connecting electrode CNE17 may be spaced apart from the fourteenth connecting electrode CNE14 in the second direction DR2.

In one or more embodiments, the seventeenth connecting electrode CNE17 may overlap the sixth area AE6b of the second active pattern ACT1b and the fifth gate signal line GSL5 in a plan view. For example, the seventeenth connecting electrode CNE17 may contact the sixth area AE6b of the second active pattern ACT1b and the fifth gate signal line GSL5 through the first contact hole CNT1. In the second sub-pixel area SPA2, the seventeenth connecting electrode CNE17 may correspond to the first terminal of the seventh transistor T7. Accordingly, the second initialization voltage VAINT may be supplied to the first terminal of the seventh transistor T7 arranged in the second sub-pixel area SPA2.

The eighteenth connecting electrode CNE18 may be arranged in the third sub-pixel area SPA3. In one or more embodiments, the eighteenth connecting electrode CNE18 may be spaced apart from the fifteenth connecting electrode CNE15 in the second direction DR2.

In one or more embodiments, the eighteenth connecting electrode CNE18 may overlap the sixth area AE6c of the third active pattern ACT1c and the fifth gate signal line GSL5 in a plan view. For example, the eighteenth connecting electrode CNE18 may contact the sixth area AE6c of the third active pattern ACT1c and the fifth gate signal line GSL5 through the first contact hole CNT1. In the third sub-pixel area SPA3, the eighteenth connecting electrode CNE18 may correspond to the first terminal of the seventh transistor T7. Accordingly, the second initialization voltage VAINT may be supplied to the first terminal of the seventh transistor T7 arranged in the third sub-pixel area SPA3.

The nineteenth connecting electrode CNE19 may be arranged in the first sub-pixel area SPA1. In one or more embodiments, the nineteenth connecting electrode CNE19 may be spaced apart from the sixteenth connecting electrode CNE16 in a direction opposite to the first direction DR1.

In one or more embodiments, the nineteenth connecting electrode CNE19 may overlap the seventh area AE7a of the first active pattern ACT1a and the eighth gate signal line GSL8 in a plan view. For example, the nineteenth connecting electrode CNE19 may contact the seventh area AE7a of the first active pattern ACT1a and the eighth gate signal line GSL8 through the first contact hole CNT1. In the first sub-pixel area SPA1, the nineteenth connecting electrode CNE19 may correspond to the second terminal of the eighth transistor T8. Accordingly, the bias voltage VOBS may be supplied to the second terminal of the eighth transistor T8 arranged in the first sub-pixel area SPA1.

The twentieth connecting electrode CNE20 may be arranged in the second sub-pixel area SPA2. In one or more embodiments, the twentieth connecting electrode CNE20 may be spaced apart from the seventeenth connecting electrode CNE17 in a direction opposite to the first direction DR1.

In one or more embodiments, the twentieth connecting electrode CNE20 may overlap each of the seventh area AE7b of the second active pattern ACT1b and the eighth gate signal line GSL8 in a plan view. For example, the twentieth connecting electrode CNE20 may contact each of the seventh area AE7b of the second active pattern ACT1b and the eighth gate signal line GSL8 through the first contact hole CNT1. In the second sub-pixel area SPA2, the twentieth connecting electrode CNE20 may correspond to the second terminal of the eighth transistor T8. Accordingly, the bias voltage VOBS may be supplied to the second terminal of the eighth transistor T8 arranged in the second sub-pixel area SPA2.

The twenty-first connecting electrode CNE21 may be arranged in the third sub-pixel area SPA3. In one or more embodiments, the twenty-first connecting electrode CNE21 may be spaced apart from the eighteenth connecting electrode CNE18 in a direction opposite to the first direction DR1.

In one or more embodiments, the twenty-first connecting electrode CNE21 may overlap each of the seventh area AE7c of the third active pattern ACT1c and the eighth gate signal line GSL8 in a plan view. For example, the twenty-first connecting electrode CNE21 may contact each of the seventh area AE7c of the third active pattern ACT1c and the eighth gate signal line GSL8 through the first contact hole CNT1. In the third sub-pixel area SPA3, the twenty-first connecting electrode CNE21 may correspond to the second terminal of the eighth transistor T8. Accordingly, the bias voltage VOBS may be supplied to the second terminal of the eighth transistor T8 arranged in the third sub-pixel area SPA3.

The first via insulating layer VIA1 may be arranged on the fourth conductive layer CL4. The first via insulating layer VIA1 may have a substantially flat upper surface. In one or more embodiments, the first via insulating layer VIA1 may include an organic insulating material, such as polyimide.

The fifth conductive layer CL5 may be arranged on the first via insulating layer VIA1. In one or more embodiments, the fifth conductive layer CL5 may include a conductive material. The fifth conductive layer CL5 may define a second contact hole CNT2 (e.g., second contact holes) for connection with lower components (e.g., lower metal layer BML, first active layer ACT1, first conductive layer CL1, second conductive layer CL2, second active layer ACT2, third conductive layer CL3, and fourth conductive layer CL4). The second contact hole CNT2 may be a hole penetrating, in a thickness direction (e.g., the third direction DR3), at least one of the barrier layer BAR, buffer layer BUF, first gate-insulating layer GIL1, second gate-insulating layer GIL2, first interlayer insulating layer ISL1, third gate-insulating layer GIL3, or the first via insulating layer VIA1.

The fifth conductive layer CL5 may include the first vertical voltage line VVL1, the second vertical voltage line VVL2, the third vertical voltage line VVL3, the fourth vertical voltage line VVL4, the fifth vertical voltage line VVL5, the sixth vertical voltage line VVL6, the twenty-second connecting electrode CNE22, the twenty-third connecting electrode CNE23, and the twenty-fourth connecting electrode CNE24.

The first vertical voltage line VVL1 may be arranged in the first sub-pixel area SPA1. The first vertical voltage line VVL1 may extend along the second direction DR2. A data voltage VDATA may be applied to the first vertical voltage line VVL1. The first vertical voltage line VVL1 may correspond to the data voltage line.

In one or more embodiments, the first vertical voltage line VVL1 may overlap the fourth connecting electrode CNE4 in a plan view. For example, the first vertical voltage line VVL1 may overlap the fourth connecting electrode CNE4 in a plan view through the second contact hole CNT2. For example, the first vertical voltage line VVL1 may be electrically connected to the second area AE2a of the first active pattern ACT1a through the fourth connecting electrode CNE4. Accordingly, the first vertical voltage line VVL1 may supply the data voltage VDATA to the first terminal of the second transistor T2 arranged in the first sub-pixel area SPA1.

The second vertical voltage line VVL2 may be arranged in the first sub-pixel area SPA1. The second vertical voltage line VVL2 may extend along the second direction DR2. A first power supply voltage ELVDD may be applied to the second vertical voltage line VVL2. The second vertical voltage line VVL2 may correspond to the first power voltage line.

In one or more embodiments, the second vertical voltage line VVL2 may overlap the tenth connecting electrode CNE10 in a plan view. For example, the second vertical voltage line VVL2 may contact the tenth connecting electrode CNE10 through the second contact hole CNT2. For example, the second vertical voltage line VVL2 may be electrically connected to the first pattern portion GP7a of the seventh gate pattern GP7 through the tenth connecting electrode CNE10. Accordingly, in the first sub-pixel area SPA1, the second vertical voltage line VVL2 may supply the first power supply voltage ELVDD to the second terminal of the first capacitor C1.

The third vertical voltage line VVL3 may be arranged in the second sub-pixel area SPA2. The third vertical voltage line VVL3 may extend along the second direction DR2. A data voltage VDATA may be applied to the third vertical voltage line VVL3. The third vertical voltage line VVL3 may correspond to the data voltage line. In one or more embodiments, the third vertical voltage line VVL3 may be spaced apart from the second vertical voltage line VVL2 in the first direction DR1.

In one or more embodiments, the third vertical voltage line VVL3 may overlap the fifth connecting electrode CNE5 in a plan view. For example, the third vertical voltage line VVL3 may overlap the fifth connecting electrode CNE5 in a plan view through the second contact hole CNT2. For example, the third vertical voltage line VVL3 may be electrically connected to the second area AE2b of the second active pattern ACT1b through the fifth connecting electrode CNE5. Accordingly, the third vertical voltage line VVL3 may supply the data voltage VDATA to the first terminal of the second transistor T2 arranged in the second sub-pixel area SPA2.

The fourth vertical voltage line VVL4 may be arranged in the second sub-pixel area SPA2. The fourth vertical voltage line VVL4 may extend along the second direction DR2. A first power supply voltage ELVDD may be applied to the fourth vertical voltage line VVL4. The fourth vertical voltage line VVL4 may correspond to the first power voltage line. In one or more embodiments, the fourth vertical voltage line VVL4 may be spaced apart from the third vertical voltage line VVL3 in the first direction DR1.

In one or more embodiments, the fourth vertical voltage line VVL4 may overlap the eleventh connecting electrode CNE11 in a plan view. For example, the fourth vertical voltage line VVL4 may contact the eleventh connecting electrode CNE11 through the second contact hole CNT2. For example, the fourth vertical voltage line VVL4 may be electrically connected to the second pattern portion GP7b of the seventh gate pattern GP7 through the eleventh connecting electrode CNE11. Accordingly, in the second sub-pixel area SPA2, the fourth vertical voltage line VVL4 may supply the first power supply voltage ELVDD to the second terminal of the first capacitor C1.

The fifth vertical voltage line VVL5 may be arranged in the third sub-pixel area SPA3. The fifth vertical voltage line VVL5 may extend along the second direction DR2. A data voltage VDATA may be applied to the fifth vertical voltage line VVL5. The fifth vertical voltage line VVL5 may correspond to the data voltage line. In one or more embodiments, the fifth vertical voltage line VVL5 may be spaced apart from the fourth vertical voltage line VVL4 in the first direction DR1.

In one or more embodiments, the fifth vertical voltage line VVL5 may overlap the sixth connecting electrode CNE6 in a plan view. For example, the fifth vertical voltage line VVL5 may overlap the sixth connecting electrode CNE6 in a plan view through the second contact hole CNT2. For example, the fifth vertical voltage line VVL5 may be electrically connected to the second area AE2c of the third active pattern ACT1c through the sixth connecting electrode CNE6. Accordingly, the fifth vertical voltage line VVL5 may provide the data voltage VDATA to the first terminal of the second transistor T2 arranged in the third sub-pixel area SPA3.

The sixth vertical voltage line VVL6 may be arranged in the third sub-pixel area SPA3. The sixth vertical voltage line VVL6 may extend along the second direction DR2. A first power supply voltage ELVDD may be applied to the sixth vertical voltage line VVL6. The sixth vertical voltage line VVL6 may correspond to the first power voltage line. In one or more embodiments, the sixth vertical voltage line VVL6 may be spaced apart from the fifth vertical voltage line VVL5 in the first direction DR1.

In one or more embodiments, the sixth vertical voltage line VVL6 may overlap the twelfth connecting electrode CNE12 in a plan view. For example, the sixth vertical voltage line VVL6 may contact the twelfth connecting electrode CNE12 through the second contact hole CNT2. For example, the sixth vertical voltage line VVL6 may be electrically connected to the third pattern portion GP7c of the seventh gate pattern GP7 through the twelfth connecting electrode CNE12. Accordingly, in the third sub-pixel area SPA3, the sixth vertical voltage line VVL6 may provide the first power supply voltage ELVDD to the second terminal of the first capacitor C1.

The twenty-second connecting electrode CNE22 may be arranged in the first sub-pixel area SPA1. The twenty-second connecting electrode CNE22 may be spaced apart from the second vertical voltage line VVL2 in the first direction DR1. In one or more embodiments, the twenty-second connecting electrode CNE22 may overlap the thirteenth connecting electrode CNE13 in a plan view. For example, the twenty-second connecting electrode CNE22 may contact the thirteenth connecting electrode CNE13 through the second contact hole CNT2. The twenty-second connecting electrode CNE22 may receive the second power supply voltage ELVSS. For example, in the first sub-pixel area SPA1, the twenty-second connecting electrode CNE22 may electrically connect the first light-emitting element EE1 and the second terminal of the sixth transistor T6 to each other.

The twenty-third connecting electrode CNE23 may be arranged in the second sub-pixel area SPA2. The twenty-third connecting electrode CNE23 may be spaced apart from the fourth vertical voltage line VVL4 in the first direction DR1. In one or more embodiments, the twenty-third connecting electrode CNE23 may overlap the fourteenth connecting electrode CNE14 in a plan view. For example, the twenty-third connecting electrode CNE23 may contact the fourteenth connecting electrode CNE14 through the second contact hole CNT2. The twenty-third connecting electrode CNE23 may receive the second power supply voltage ELVSS. For example, in the second sub-pixel area SPA2, the twenty-third connecting electrode CNE23 may electrically connect the second light-emitting element EE2 and the second terminal of the sixth transistor T6 to each other.

The twenty-fourth connecting electrode CNE24 may be arranged in the third sub-pixel area SPA3. The twenty-fourth connecting electrode CNE24 may be spaced apart from the sixth vertical voltage line VVL6 in the first direction DR1. In one or more embodiments, the twenty-fourth connecting electrode CNE24 may overlap the fifteenth connecting electrode CNE15 in a plan view. For example, the twenty-fourth connecting electrode CNE24 may contact the fifteenth connecting electrode CNE15 through the second contact hole CNT2. The twenty-fourth connecting electrode CNE24 may receive the second power supply voltage ELVSS. For example, in the third sub-pixel area SPA3, the twenty-fourth connecting electrode CNE24 may electrically connect the third light-emitting element EE3 and the second terminal of the sixth transistor T6 to each other.

The second via insulating layer VIA2 may be arranged on the fifth conductive layer CL5. The second via insulating layer VIA2 may have a substantially planar upper surface. In one or more embodiments, the second via insulating layer VIA2 may include an organic insulating material, such as polyimide. The first, second, and third pixel electrodes PXE1, PXE2, and PXE3 may contact the fifth conductive layer CL5 through holes that penetrate the second via insulating layer VIA2 in a thickness direction.

FIG. 20 is a diagram for comparing a magnitude of driving current delivered to each of the first, second, and third sub-pixels.

Referring to FIGS. 2 and 20, in the first channel area CA1a of the first active pattern ACT1a, charge carriers (e.g., holes or electrons) passing from the first area AE1a through the first channel area CA1a to the fourth area AE4a may move in the second direction DR2. Thus, a first channel length L1 of the first transistor T1 arranged in the first sub-pixel area SPA1 may be a length in the second direction DR2 of the first channel area CA1a. Also, a width W1 of the first transistor T1 arranged in the first sub-pixel area SPA1 may be a length or width in the first direction DR1 of the first channel area CA1a.

In the first channel area CA1b of the second active pattern ACT1b, charge carriers (e.g., holes or electrons) passing from the first area AE1b through the first channel area CA1b to the fourth area AE4b may move in the first direction DR1. Thus, a second channel length L2 of the first transistor T1 arranged in the second sub-pixel area SPA2 may be a length in the first direction DR1 of the first channel area CA1b. In addition, a width W2 of the first transistor T1 arranged in the second sub-pixel area SPA2 may be a length or width in the second direction DR2 of the first channel area CA1b.

In the first channel area CA1c of the third active pattern ACT1c, charge carriers (e.g., holes or electrons) passing from the first area AE1c through the first channel area CA1c to the fourth area AE4c may move in the first direction DR1. Thus, a third channel length L3 of the first transistor T1 arranged in the third sub-pixel area SPA3 may be a length in the first direction DR1 of the first channel area CA1c. In addition, a third channel width W3 of the first transistor T1 arranged in the third sub-pixel area SPA3 may be a length or width in the second direction DR2 of the first channel area CA1c.

In one or more embodiments, the magnitude of the current flowing through the first transistor T1 arranged in the first sub-pixel area SPA1 may be greater than the magnitude of the current flowing through the first transistor T1 arranged in the second sub-pixel area SPA2. For example, the current flowing through the first transistor T1 may be about four times or more than the current flowing through the first transistor T1 arranged in the second sub-pixel area SPA2. For example, the current may be about four times or more to about six times or less, and for example about five times.

In one or more embodiments, the magnitude of the current flowing through the first transistor T1 arranged in the first sub-pixel area SPA1 may be greater than the current flowing through the first transistor T1 arranged in the third sub-pixel area SPA3. For example, the current may be about four times or more, for example about four to six times, and for example about five times the current in the third sub-pixel area SPA3.

In the disclosure, the current flowing through the first transistor T1 arranged in the first sub-pixel area SPA1 may be referred to as a first driving current, and the current flowing through the first transistor T1 arranged in the second or third sub-pixel area SPA2 or SPA3 may be referred to as a second driving current.

However, magnitude of the current flowing through the first transistor T1 according to the embodiments of the present disclosure may not be limited thereto. When at least one of the second active pattern ACT1b or the third active pattern ACT1c has the same structure as the first active pattern ACT1a, the magnitude of the current flowing through the first transistor T1 arranged in the second sub-pixel area SPA2 or the third sub-pixel area SPA3 may be substantially a same as the magnitude of the current flowing through the first transistor T1 arranged in the first sub-pixel area SPA1.

As described above, in the display device DD according to one or more embodiments of the present disclosure, the first gate pattern GP1 included in the first driving transistor arranged in the first sub-pixel area SPA1 may include a first portion GP1a that does not overlap with the first active pattern ACT1a in a plan view and a second portion GP1c that overlaps with the first active pattern ACT1a in a plan view. Accordingly, the length in the second direction DR2 of the first channel area CA1a of the first active pattern ACT1a included in the first driving transistor arranged in the first sub-pixel area SPA1 may be less than the length in the first direction DR1 of the first channel area CA1b of the second active pattern ACT1b included in the first driving transistor arranged in the second sub-pixel area SPA2. As a result, the width-to-length ratio corresponding to the channel width and channel length may be greater for the first driving transistor included in the first sub-pixel SPX1 than for the second driving transistor. Therefore, because a current (e.g., driving current) flowing through the first driving transistor included in the first sub-pixel SPX1 that drives a first light-emitting element for emitting red light may be greater than (e.g., may have greater intensity than) a current (e.g., driving current) flowing through the second driving transistor, a power consumption efficiency of the display device DD may be improved.

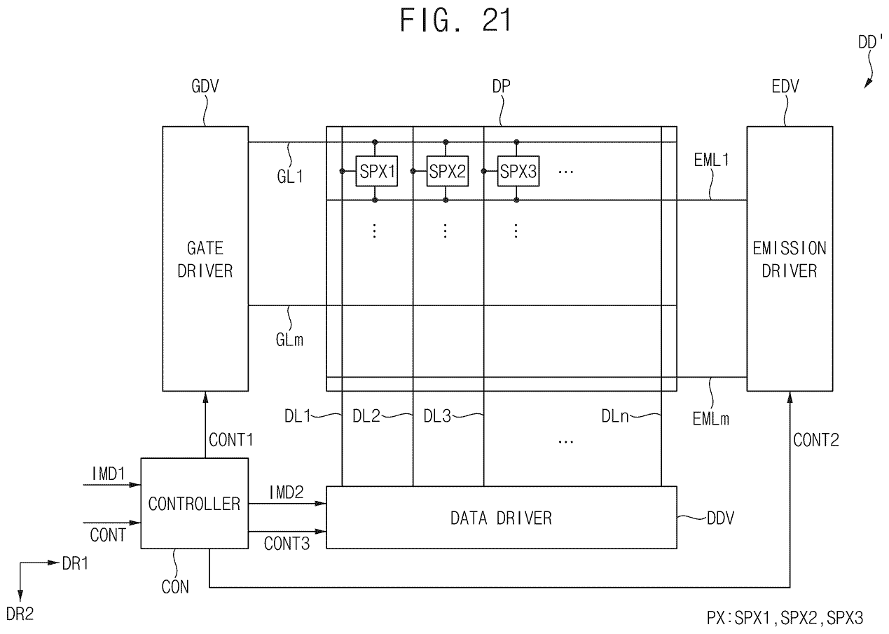

FIG. 21 is a block diagram illustrating a display device according to one or more other embodiments of the present disclosure.

Referring to FIG. 21, the display device DD′ may be substantially a same as or similar to the display device DD described with reference to FIG. 1, except for the light-emitting control lines EML1, . . . , EMLm. Hereinafter, descriptions that overlap with those given with reference to FIG. 1 may be omitted or briefly described.

Referring to FIG. 21, the display device DD′ may include a plurality of light-emitting control lines EML1, . . . , EMLm connected to each of a plurality of pixels PX. One of the plurality of light-emitting control lines EML1, . . . , EMLm may be electrically connected to each of the pixels arranged in a same row. For example, the first light-emitting control line EML1 may be connected to each of the first to third sub-pixels SPX1, SPX2, and SPX3 that emit light of different colors.

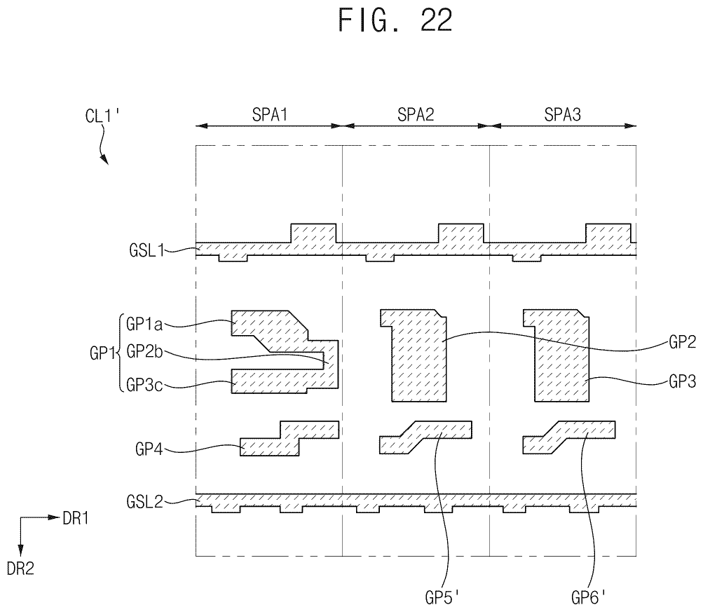

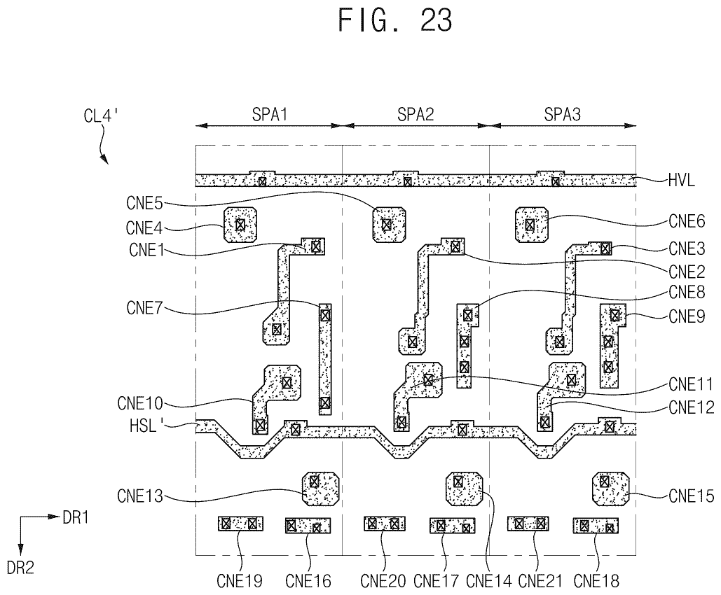

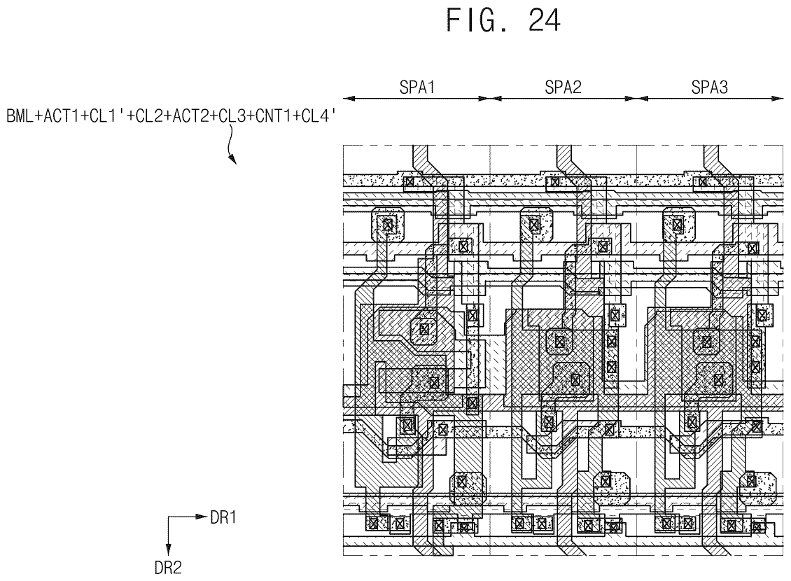

FIGS. 22, 23, and 24 are layout views for explaining a pixel included in the display device of FIG. 22.

The layout views described with reference to FIGS. 22, 23, and 24 may be substantially a same as or similar to the layout diagrams described with reference to FIGS. 4, 5, 6, 7, 8, 9, 10, 11, 12, 13, 14, 15, 16, 17, and 18, except for the fifth gate pattern GP5′, the sixth gate pattern GP6′, the horizontal signal line HSL′, and the light-emitting control lines EML1, . . . , EMLm. Hereinafter, descriptions that overlap with those provided with reference to FIGS. 4, 5, 6, 7, 8, 9, 10, 11, 12, 13, 14, 15, 16, 17, and 18 may be omitted or briefly described.

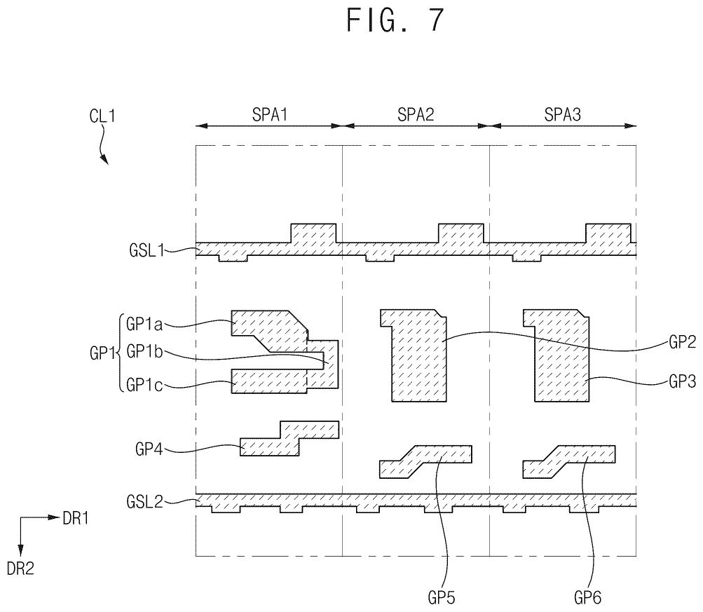

Referring to FIGS. 22, 23, and 24, a first conductive layer CL1′ may include a fifth gate pattern GP5′ and a sixth gate pattern GP6′. The fifth gate pattern GP5′ of FIG. 22 may be located in a direction opposite to the second direction DR2 from a location of the fifth gate pattern GP5 of FIG. 7. In other words, the fifth gate pattern GP5′ of FIG. 22 may be located closer to the second gate pattern GP2 than the fifth gate pattern GP5 of FIG. 7. Likewise, the sixth gate pattern GP6′ of FIG. 22 may be located in a direction opposite to the second direction DR2 from the position of the sixth gate pattern GP6 of FIG. 7. In other words, the sixth gate pattern GP6′ of FIG. 22 may be located closer to the third gate pattern GP3 than the sixth gate pattern GP6 of FIG. 7.

A fourth conductive layer CL4′ may include a horizontal signal line HSL′. In one or more embodiments, the horizontal signal line HSL′ may overlap with each of the fourth gate pattern GP4, the fifth gate pattern GP5′, and the sixth gate pattern GP6′ in a plan view. For example, the horizontal signal line HSL′ may contact each of the fourth gate pattern GP4, the fifth gate pattern GP5′, and the sixth gate pattern GP6′ through the first contact hole CNT1 (e.g., first contact holes). Accordingly, the horizontal signal line HSL′ may provide one light-emitting signal (e.g., the light-emitting signal EM of FIG. 2) to each of the fourth gate pattern GP4, the fifth gate pattern GP5′, and the sixth gate pattern GP6′.

In other words, the horizontal signal line HSL′ may be connected to the gate terminal of each of the fifth transistors T5 arranged in the first sub-pixel areas SPA1, the fifth transistors T5 arranged in the second sub-pixel areas SPA2, and the fifth transistors T5 arranged in the third sub-pixel areas SPA3.

As described above, in the display device DD′ according to one or more embodiments of the present disclosure, the first gate pattern GP1 included in the first driving transistor arranged in the first sub-pixel area SPA1 may include a first portion GP1a that does not overlap with the first active pattern ACT1a in a plan view and a second portion GP1c that overlaps with the first active pattern ACT1a in a plan view. Accordingly, the length in the second direction DR2 of the first channel area CA1a of the first active pattern ACT1a included in the first driving transistor arranged in the first sub-pixel area SPA1 may be less than the length in the first direction DR1 of the first channel area CA1b of the second active pattern ACT1b included in the first driving transistor arranged in the second sub-pixel area SPA2. Thus, the width-to-length ratio of the channel may be greater in the first driving transistor included in the first sub-pixel SPX1 than in the second driving transistor. Therefore, because a current flowing through the first driving transistor included in the first sub-pixel SPX1 that drives a first light-emitting element for emitting red light may be greater than a current flowing through the second driving transistor, a power consumption efficiency of the display device DD′ may be improved.

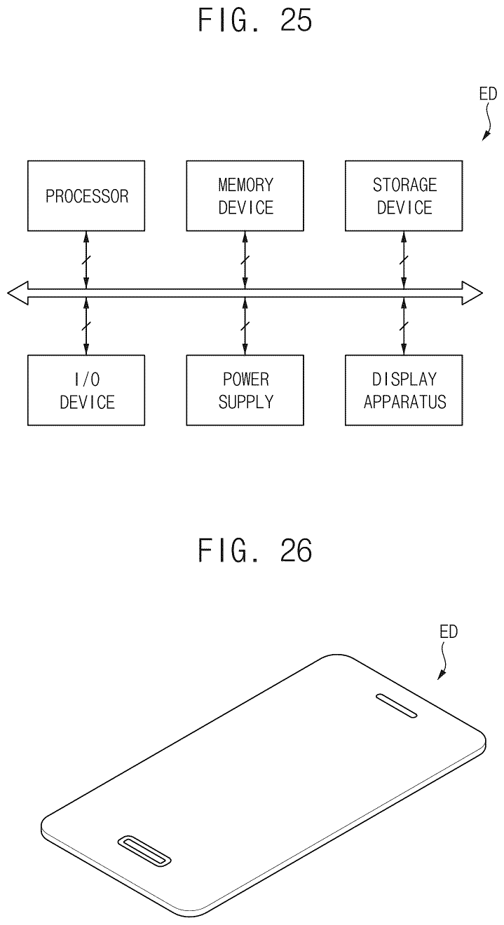

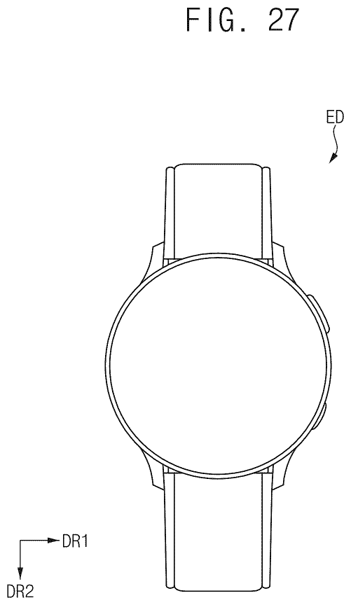

FIG. 25 is a block diagram illustrating an electronic device according to one or more embodiments of the present disclosure. FIG. 26 is a diagram illustrating the electronic device of FIG. 25 implemented as a smartphone.

Referring to FIGS. 25 and 26, the electronic device ED may include a processor, a memory device, a storage device, an input/output device, a power supply, and a display device. In this case, the display device may be the display device DD or DD′ of FIG. 1 or FIG. 21. The electronic device ED may further include various ports capable of communicating with a video card, sound card, memory card, USB device, and/or the like, or capable of communicating with other systems.

The processor may perform corresponding calculations or tasks. In one or more embodiments, the processor may be a microprocessor, a central processing unit, or an application processor. The processor may be connected to other components via an address bus, a control bus, and a data bus. In one or more embodiments, the processor may be connected to an expansion bus, such as a Peripheral Component Interconnect (PCI) bus.

Referring further to FIGS. 1 and 21, the processor may output input image data IMD1 and an input control signal CONT to a driving controller CON. For example, the processor may output the input image data IMD1 and the input control signal CONT to the display device DD or DD′, and accordingly, the display device DD or DD′ may operate based on the input image data IMD1 and the input control signal CONT.

The memory device may store data suitable for the operation of the electronic device ED. For example, the memory device may include non-volatile memory devices, such as Erasable Programmable Read-Only Memory (EPROM), Electrically Erasable Programmable Read-Only Memory (EEPROM), flash memory device, Phase Change Random Access Memory (PRAM), Resistance Random Access Memory (RRAM), Nano Floating Gate Memory (NFGM), Polymer Random Access Memory (PoRAM), Magnetic Random Access Memory (MRAM), and Ferroelectric Random Access Memory (FRAM), and/or volatile memory devices, such as Dynamic Random Access Memory (DRAM), Static Random Access Memory (SRAM), and mobile (DRAM).

The storage device may include a Solid State Drive (SSD), Hard Disk Drive (HDD), CD-ROM, and/or the like. The input/output device may include input means, such as a keyboard, keypad, touchpad, touchscreen, and mouse, and output means, such as a speaker and printer. In one or more embodiments, the display device may also be included in the input/output device. The power supply may supply power suitable for the operation of the electronic device ED. The display device may be connected to other components via the buses or other communication links.

In one or more embodiments, as illustrated in FIG. 26, the electronic device ED may be implemented as a smartphone. However, this is merely exemplary, and the electronic device ED may not be limited thereto. For example, the electronic device ED may be implemented as a mobile phone, video phone, smart pad, smartwatch, tablet PC, vehicle navigation system, computer monitor, notebook, head-mounted display device, and/or the like. In addition, the electronic device may be a television, monitor, notebook computer, or tablet. Further, the electronic device may be an automobile.

FIG. 27 is a diagram illustrating the electronic device of FIG. 25 implemented as a smartwatch.

Referring to FIGS. 25 and 27, the electronic device ED may be a smartwatch, and the smartwatch may be an electronic device utilizing an ultra-high-resolution display panel (e.g., the display panel DP of FIG. 1 or FIG. 21). The smartwatch may include a main body for displaying an image and/or a clock, and a wearing portion (e.g., wrist, and/or the like) for being worn on a user's body. For example, the main body may display an image according to an operation mode, display a clock, or display both an image and a clock concurrently or substantially simultaneously. For example, the wearing portion may be a strap, chain, bracelet, and/or the like. In one or more embodiments, the main body includes the ultra-high-resolution display panel, and the image and the clock may be displayed by pixels (e.g., the pixel PX of FIG. 1) included in the ultra-high-resolution display panel.

The devices according to the embodiments may be applied to a display device included in a computer, a notebook, a mobile phone, a smartphone, a smart pad, a PMP, a PDA, an MP3 player, or the like.

Although the devices according to the embodiments have been described with reference to the drawings, the illustrated embodiments are examples, and may be modified and changed by a person having ordinary knowledge in the relevant technical field without departing from the technical spirit described in the following claims, with functional equivalents thereof to be included therein.

What is claimed is:

1. A display device comprising:
a first active pattern comprising a first driving channel area having a first channel length;
a second active pattern spaced apart from the first active pattern in a plan view, and comprising a second driving channel area having a second channel length that is greater than the first channel length;
a first gate pattern above the first active pattern, and comprising:
a first portion spaced apart from the first active pattern;
a second portion overlapping the first driving channel area; and
a connecting portion bent from the first portion toward the second portion and connecting the first portion and the second portion;
a second gate pattern above the second active pattern and overlapping the second driving channel area;
a first light-emitting element above the first active pattern, electrically connected to the first active pattern, and configured to emit a first light; and
a second light-emitting element above the second active pattern, electrically connected to the second active pattern, and configured to emit a second light that is different from the first light.

2. The display device of claim 1, wherein the second active pattern is spaced apart from the first active pattern in a first direction, and
wherein the second portion is spaced apart from the first portion in a second direction crossing the first direction.

3. The display device of claim 2, wherein the first channel length is defined as a length of the first driving channel area in the second direction, and
wherein the second channel length is defined as a length of the second driving channel area in the first direction.

4. The display device of claim 3, wherein a first driving transistor comprises the first active pattern and the first gate pattern, and is configured to transmit a driving current to the first light-emitting element, and
wherein a second driving transistor comprises the second active pattern and the second gate pattern, and is configured to transmit the driving current to the second light-emitting element.

5. The display device of claim 4, wherein a first channel width of the first driving transistor is defined as a width of the first driving channel area in the first direction, and
wherein a second channel width of the second driving transistor is defined as a width of the second driving channel area in the second direction.

6. The display device of claim 5, wherein a width-to-length ratio of the first channel width to the first channel length is greater than a width-to-length ratio of the second channel width to the second channel length.

7. The display device of claim 4, further comprising:
a first upper pattern portion at a layer between the first gate pattern and the first light-emitting element, and overlapping the first gate pattern; and
a second upper pattern portion at a layer between the second gate pattern and the second light-emitting element, and overlapping the second gate pattern.

8. The display device of claim 7, wherein a first hole exposing an upper surface of the first portion is defined in the first upper pattern portion.

9. The display device of claim 7, wherein the first upper pattern portion overlaps an entirety of the first gate pattern.

10. The display device of claim 7, wherein an area of a portion where the first gate pattern overlaps the first upper pattern portion is greater than an area of a portion where the second gate pattern overlaps the second upper pattern portion.

11. The display device of claim 7, wherein the first gate pattern and the first upper pattern portion define a first storage capacitor connected to a gate terminal of the first driving transistor, and
wherein the second gate pattern and the second upper pattern portion define a second storage capacitor connected to a gate terminal of the second driving transistor.

12. The display device of claim 4, further comprising:
a first light-emitting control transistor connected to a first terminal of the first driving transistor;
a first operation control transistor connected to a second terminal of the first driving transistor opposite to the first terminal of the first driving transistor;
a second light-emitting control transistor connected to a first terminal of the second driving transistor; and
a second operation control transistor connected to a second terminal of the second driving transistor opposite to the first terminal of the second driving transistor.

13. The display device of claim 12, wherein a channel width of the first light-emitting control transistor is greater than a channel width of the second light-emitting control transistor.

14. The display device of claim 12, wherein a channel width of the first operation control transistor is greater than a channel width of the second operation control transistor.

15. A display device comprising:.
a first light-emitting element configured to emit a first light;
a first driving transistor configured to transmit a first driving current to the first light-emitting element, and having a first channel length and a first channel width;
a second light-emitting element configured to emit a second light that is different from the first light; and
a second driving transistor configured to transmit a second driving current to the second light-emitting element, having a second channel length and a second channel width, and having a width-to-length ratio of the second channel width to the second channel length that is less than a width-to-length ratio of the first channel width to the first channel length of the first driving transistor.

16. The display device of claim 15, wherein the first channel length of the first driving transistor is less than the second channel length of the second driving transistor.

17. The display device of claim 15, wherein an intensity of the first driving current is greater than an intensity of the second driving current.

18. The display device of claim 15, further comprising:
a first light-emitting control transistor comprising a first terminal connected to a first terminal of the first driving transistor, and a second terminal connected to the first light-emitting element;
a first operation control transistor comprising a first terminal configured to receive a driving voltage, and a second terminal connected to a second terminal of the first driving transistor opposite to the first terminal of the first driving transistor;
a second light-emitting control transistor comprising a first terminal connected to a first terminal of the second driving transistor, and a second terminal connected to the second light-emitting element; and
a second operation control transistor comprising a first terminal configured to receive the driving voltage, and a second terminal connected to a second terminal of the second driving transistor opposite to the first terminal of the second driving transistor,
wherein a channel width of the first light-emitting control transistor is greater than a channel width of the second light-emitting control transistor.

19. The display device of claim 18, wherein a channel width of the first operation control transistor is greater than a channel width of the second operation control transistor.

20. An electronic device comprising:
a processor configured to output image data and an input control signal; and
a display device configured to be driven based on the image data and the input control signal, and comprising:
a first active pattern comprising a first driving channel area having a first channel length;
a second active pattern spaced apart from the first active pattern in a plan view, and comprising a second driving channel area having a second channel length that is greater than the first channel length;
a first gate pattern above the first active pattern, and comprising:
a first portion spaced apart from the first active pattern;
a second portion overlapping the first driving channel area; and
a connecting portion bent from the first portion toward the second portion, and connecting the first portion and the second portion;
a second gate pattern above the second active pattern, and overlapping the second driving channel area;
a first light-emitting element above the first active pattern, electrically connected to the first active pattern, and configured to emit a first light; and
a second light-emitting element above the second active pattern, electrically connected to the second active pattern, and configured to emit a second light that is different from the first light.
